(19) United States
(12) Patent Application Publication
(10) Pub. No.: US 2014/0001581 A1
(43) Pub. Date: Jan. 2, 2014

(54) MEMS MICROPHONE AND FORMING METHOD THEREFOR

(71) Applicant: Lianjun Liu, Tianjin (CN)

(72) Inventor: Lianjun Liu, Tianjin (CN)

(73) Assignee: MEMSEN ELECTRONICS INC, Tianjin (CN)

(21) Appl. No.: 14/004,575

(22) PCT Filed: Feb. 22, 2012
(86) PCT No.: PCT/CN2012/071435

§ 371 Date: Sep. 11, 2013

(30) Foreign Application Priority Data
Mar. 15, 2011 (CN) 201110061552.X

(51) Int. Cl. B81B 3/00; B81C 1/00

(52) U.S. Cl. CPC B81B 3/0018; B81C 1/00158
USPC 257/416; 438/53

(57) ABSTRACT

A micro-electro-mechanical system (MEMS) microphone may include a sensitive diaphragm and a fixed electrode corresponding to the sensitive diaphragm; at least one sensitive diaphragm support located on the surface of the sensitive diaphragm corresponding to the fixed electrode; and a sensitive diaphragm support arm coupled to the sensitive diaphragm support.

This application claims the priority of Chinese Patent Application No. 201110061552.X, entitled “MEMS MICROPHONE AND FORMING METHOD THEREFOR”, filed with the Chinese Patent Office on Mar. 15, 2011, which is hereby incorporated by reference in its entirety.

### FIELD OF THE INVENTION

The present invention relates to the field of micro-electro-mechanical system process, and particularly to a MEMS microphone and a forming method therefor.

### BACKGROUND OF THE INVENTION

A Micro-Electro-Mechanical System (MEMS) microphone formed by a micro electronic mechanical system process has become one of the best candidates for replacing an Electret Condenser Microphone (ECM) with organic film, due to the characteristics of miniaturization and lightweight of the MEMS microphone.

The MEMS microphone is a miniature microphone made by etching a pressure sensing diaphragm on a semiconductor via micro-electro-mechanical system process, and is widely used in mobile phone, headset, notebook computer, video camera and car. A structure of a MEMS microphone was disclosed in a U.S. patent document which is published with U.S. Pat. No. 2,389,65. Referring to FIG. 1, the MEMS microphone includes a substrate 100, within which an acoustic signal transmission hole is formed; a dielectric layer 140 which is located on the surface of the substrate, where a cavity 110 in communication with the acoustic signal transmission hole is formed within the dielectric layer 140; a vibrating diaphragm 120 which is located within the cavity 110 and located on the substrate 100; a interconnect 121 located on the surface of the vibrating diaphragm 120; a fixed electrode 130 which is located within the cavity, located on the interconnect 121 and electrically isolated from the interconnect 121, where a through hole 131 is formed within the fixed electrode. Furthermore, referring to FIG. 2, which is a cross-sectional view along the AA direction in FIG. 1, the interconnect 121 has a fixed electrode 122 which is in the same plane as the interconnect 121 and is integrated with the interconnect 121, and the fixed electrode 122 is electrically connected to an electrode formed within the dielectric layer 140. When an acoustic signal is transmitted to the vibrating diaphragm 120 through the acoustic signal transmission hole, the vibrating diaphragm 120 will vibrate according to the acoustic signal, so as to change the electrostatic capacitance of a parallel-plate capacitor provided with the interconnect 121 located on the surface of the vibrating diaphragm 120 and the fixed electrode 130, and output an electric signal corresponding to the acoustic signal by the interconnect 121.

With the further miniaturization of the MEMS microphone, the structure of the MEMS microphone will become even more sensitive to stress, such as the stress between the vibrating diaphragm 120 and the interconnect 121, and the stress caused by the design of the fixed electrode 122 integrated with the interconnect 121 of the MEMS microphone, which results in that the production yield of the MEMS microphone is reduced and it is difficult to further improve the product performance and miniaturization of the MEMS microphone as well.

### SUMMARY OF THE INVENTION

An embodiment of the present invention provides a MEMS microphone which has a small size and is less affected by the stress.

To solve the above mentioned problems, the MEMS microphone is provided according to the embodiments of the present invention, and the MEMS microphone includes:

a sensitive diaphragm and a fixed electrode corresponding to the sensitive diaphragm;

at least one sensitive diaphragm support located on the surface of the sensitive diaphragm corresponding to the fixed electrode; and a sensitive diaphragm support arm coupled to the sensitive diaphragm support.

Alternatively, the sensitive diaphragm support is located in the center of the surface of the sensitive diaphragm corresponding to the fixed electrode, in the case where the number of the sensitive diaphragm support is 1.

Alternatively, the center of a pattern formed by a plurality of sensitive diaphragm supports coincides with the center of the surface of the sensitive diaphragm corresponding to the fixed electrode, in the case where the number of the sensitive diaphragm support is more than 1.

Alternatively, the fixed electrode, the sensitive diaphragm support and the sensitive diaphragm support arm are made from the same material.

Alternatively, the fixed electrode, the sensitive diaphragm support and the sensitive diaphragm support arm are made from low stress polycrystalline silicon.

Alternatively, the sensitive diaphragm support is made from a dielectric material.

Alternatively, the sensitive diaphragm support is made from silicon oxide.

Alternatively, the sensitive diaphragm support and the sensitive diaphragm are made from the same material.

Alternatively, the sensitive diaphragm support and the sensitive diaphragm are made from low stress polycrystalline silicon.

Alternatively, the MEMS microphone further includes: a travel stopper which is corresponding to the sensitive diaphragm and used to prevent the sensitive diaphragm from contacting the fixed electrode.

Alternatively, the travel stopper is made from a conductive material.

A method for forming the MEMS microphone is further provided according to the embodiment of the present embodiment, and the method includes:

forming a sensitive diaphragm;

forming a fixed electrode;

forming at least one sensitive diaphragm support; and

forming a sensitive diaphragm support arm;

wherein the fixed electrode is corresponding to the sensitive diaphragm,

the sensitive diaphragm support is located on the surface of the sensitive diaphragm corresponding to the fixed electrode, and

the sensitive diaphragm support arm is coupled to the sensitive diaphragm support.

Alternatively, the method for forming the MEMS microphone may include:

forming a first electrode on a surface of a substrate;

forming a dielectric layer by which the first electrode is covered, and forming at least one sensitive diaphragm support within the dielectric layer;

forming a second electrode opposite to the first electrode, wherein the first electrode is the sensitive diaphragm and the second electrode is the fixed electrode; or the first electrode is the fixed electrode and the second electrode is the sensitive diaphragm; and

forming the sensitive diaphragm support arm, which is coupled to the sensitive diaphragm support on the surface of the sensitive diaphragm corresponding to the fixed electrode.

Alternatively, the method for forming the MEMS microphone may include:

forming the sensitive diaphragm on the surface of the substrate;

forming the dielectric layer by which the sensitive diaphragm is covered, and

forming, within the dielectric layer, a through hole through which the surface of the sensitive diaphragm is exposed;

filling a low stress conductive material into the through hole, to form the sensitive diaphragm support in the position of the through hole and to form a low stress conductive layer on the surface of the dielectric layer; and

etching the low stress conductive layer to form, on the surface of the dielectric layer, the sensitive diaphragm support arm which is coupled to the sensitive diaphragm support, and the fixed electrode corresponding to the sensitive diaphragm.

Alternatively, the method for forming the MEMS microphone may include:

forming the sensitive diaphragm on the surface of the substrate;

forming the dielectric layer by which the sensitive diaphragm is covered;

forming, on the surface of the dielectric layer, the sensitive diaphragm support arm and the fixed electrode corresponding to the sensitive diaphragm, wherein the sensitive diaphragm support arm has a portion which has a position corresponding to the position of the sensitive diaphragm; and

etching the dielectric layer to form the sensitive diaphragm support coupling the sensitive diaphragm support arm to the sensitive diaphragm.

Alternatively, the method for forming the MEMS microphone may include:

forming, on the surface of the substrate, the sensitive diaphragm support arm and the fixed electrode;

forming the dielectric layer by which the sensitive diaphragm support arm and the fixed electrode are covered, and forming, within the dielectric layer, a through hole through which the surface of the sensitive diaphragm support arm is exposed;

filling a low stress conductive material into the through hole, to form the sensitive diaphragm support in the position of the through hole and to form a low stress conductive layer on the surface of the dielectric layer; and

etching the low stress conductive layer to form, on the surface of the dielectric layer, the sensitive diaphragm which is coupled to the sensitive diaphragm support and corresponding to the fixed electrode.

Alternatively, the method for forming the MEMS microphone may include:

forming, on the surface of the substrate, the sensitive diaphragm support arm and the fixed electrode;

forming the dielectric layer by which the sensitive diaphragm support arm and the fixed electrode are covered;

forming, on the surface of the dielectric layer, the sensitive diaphragm corresponding to the fixed electrode; and

etching the dielectric layer to form the sensitive diaphragm support coupling the sensitive diaphragm support arm to the sensitive diaphragm.

Alternatively, the method for forming the MEMS microphone may further include a step of forming a travel stopper, wherein the travel stopper is corresponding to the sensitive diaphragm and is used to prevent the sensitive diaphragm from contacting the fixed electrode.

Alternatively, the travel stopper may be formed in the same process step as the fixed electrode, or the travel stopper may be formed in the same process as the sensitive diaphragm support.

The embodiments of the present invention has the following advantages as compared with the prior art. The MEMS microphone formed according to the embodiment of the present invention adopts a structure including a sensitive diaphragm support located in the center of the surface of the sensitive diaphragm and a sensitive diaphragm support arm, so that the influence of the external on the stress of the sensitive diaphragm is low, and thereby the sensitivity of the MEMS microphone is improved. The size and the production cost of the MEMS microphone according to the embodiment of the present invention can be further reduced, because there is no stress influence on the MEMS microphone.

Furthermore, the MEMS microphone formed according to the embodiments of the present invention further has a travel stopper, so as to protect the sensitive diaphragm and the fixed electrode. Specifically, the travel stopper may be corresponding to the edge area of the sensitive diaphragm, and the travel stopper can prevent the sensitive diaphragm from sticking to the fixed electrode, thereby increase the operating lifetime of the MEMS microphone.

### BRIEF DESCRIPTION OF THE DRAWINGS

FIG. 1 is a schematic structural diagram of an existing MEMS microphone;

FIG. 2 is a cross-sectional view along the AA direction in FIG. 1;

FIG. 3 is a schematic flowchart of a method for forming a MEMS microphone according to an embodiment of the present invention;

FIG. 4 is a schematic flowchart of a method for forming a MEMS microphone according to a first embodiment of the present invention;

FIG. 5 to FIG. 13 are process diagrams of the method for forming a MEMS microphone according to the first embodiment of the present invention;

FIG. 14 is a schematic flowchart of a method for forming a MEMS microphone according to a second embodiment of the present invention;

FIG. 15 to FIG. 24 are process diagrams of the method for forming a MEMS microphone according to the second embodiment of the present invention;

FIG. 25 is a schematic flowchart of a method for forming a MEMS microphone according to a third embodiment of the present invention;

FIG. 26 is a schematic flowchart of a method for forming a MEMS microphone according to a fourth embodiment of the present invention;

FIG. 27 to FIG. 29 are process diagrams of the method for forming a MEMS microphone according to the fourth embodiment of the present invention;

FIG. 30 is a schematic flowchart of a method for forming a MEMS microphone according to a fifth embodiment of the present invention;

FIG. 31 to FIG. 33 are process diagrams of the method for forming a MEMS microphone according to the fifth embodiment of the present invention;

FIG. 34 is a schematic flowchart of a method for forming a MEMS microphone according to a sixth embodiment of the present invention;

FIG. 35 to FIG. 37 are process diagrams of the method for forming a MEMS microphone according to the sixth embodiment of the present invention;

FIG. 38 is a schematic flowchart of a method for forming a MEMS microphone according to a seventh embodiment of the present invention;

FIG. 39 to FIG. 45 are process schematic diagrams of the method for forming a MEMS microphone according to the seventh embodiment of the present invention;

FIG. 46 is a schematic flowchart of a method for forming a MEMS microphone according to an eighth embodiment of the present invention;

FIG. 47 is a schematic structural diagram of the MEMS microphone according to the eighth embodiment of the present invention;

FIG. 48 is a schematic flowchart of a method for forming a MEMS microphone according to a ninth embodiment of the present invention;

FIG. 49 is a schematic diagram of a MEMS microphone according to another embodiment of the present invention;

FIG. 50 is a schematic diagram of a MEMS microphone according to yet another embodiment of the present invention; and

FIG. 51 is a schematic diagram of a MEMS microphone according to still another embodiment of the present invention.

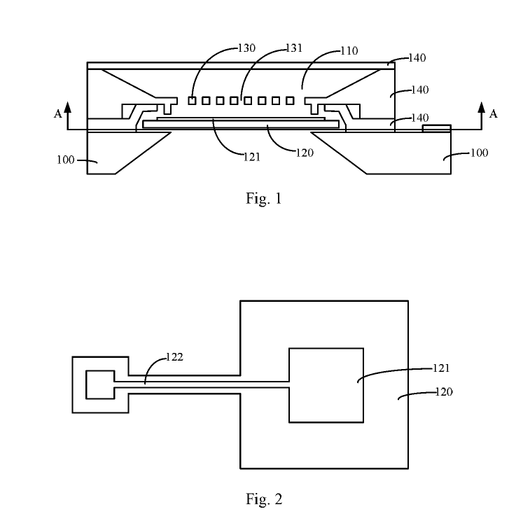

### DETAILED DESCRIPTION OF THE INVENTION

It is difficult to further miniaturize the existing MEMS microphone, due to the influence of the stress on the MEMS microphone. It has been found by the inventor of the present invention through lots of research that the problem of the stress in the existing MEMS microphone results in large size and high production cost of the MEMS microphone. By way of example, in the U.S. patent document published with U.S. Pat. No. 2,389,65, the MEMS microphone adopts a structure in which the interconnect 121 is formed on the surface of the vibrating diaphragm 120, and the interconnect 121 has a fixed electrode 122 which is in the same plane as the interconnect 121 and is integrated with the interconnect 121. The structure results in that the production yield of the MEMS microphone is reduced and it is difficult to further improve the product performance and miniaturization of the MEMS microphone.

Therefore, an optimized method for forming a MEMS microphone is proposed by the inventor of the present invention. The method includes the following steps:

forming a sensitive diaphragm;

forming a fixed electrode;

forming at least one sensitive diaphragm support; and

forming a sensitive diaphragm support arm;

wherein the fixed electrode is corresponding to the sensitive diaphragm, the sensitive diaphragm support is located on the surface of the sensitive diaphragm corresponding to the fixed electrode, and

the sensitive diaphragm support arm is coupled to the sensitive diaphragm support.

The method further includes a step of forming a travel stopper used to prevent the sensitive diaphragm from contacting the fixed electrode.

The MEMS microphone formed by the forming method described above includes: a sensitive diaphragm and a fixed electrode corresponding to the sensitive diaphragm, wherein the sensitive diaphragm has a first surface opposite to the fixed electrode; at least one sensitive diaphragm support located on the first surface of the sensitive diaphragm; and a sensitive diaphragm support arm coupled to the sensitive diaphragm support.

The MEMS microphone formed according to the embodiments of the present invention adopts a structure including a sensitive diaphragm support located in the center of the surface of the sensitive diaphragm and a sensitive diaphragm support arm, so that the influence of the external on the stress of the sensitive diaphragm is small, and thereby the sensitivity of the MEMS microphone will be improved. The size and the production cost of the MEMS microphone according to the embodiment of the present invention can be further reduced because that there is no stress influence on the MEMS microphone.

Furthermore, in order to protect the sensitive diaphragm and the fixed electrode, the MEMS microphone formed according to the embodiment of the present invention further is provided with a travel stopper. Specifically, the travel stopper is corresponding to the edge area of the sensitive diaphragm, and the travel stopper can prevent the sensitive diaphragm from sticking to the fixed electrode, thereby increase the operating lifetime of the MEMS microphone.

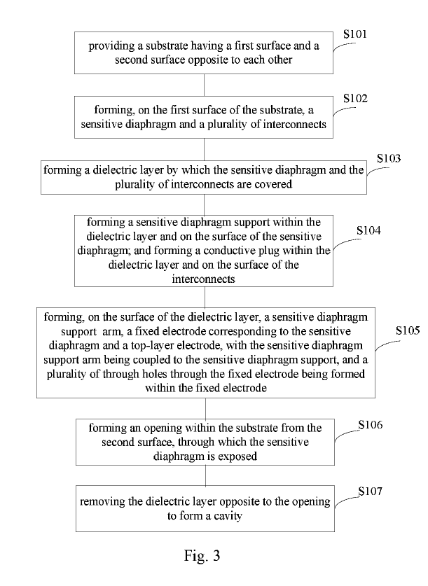

Specifically, an optimized method for forming a MEMS microphone is proposed by the inventor of the present invention. Referring to FIG. 3, the method includes the following steps:

Step S101, providing a substrate having a first surface and a second surface opposite to each other;

Step S102, forming, on the first surface of the substrate, a sensitive diaphragm and a plurality of interconnects;

Step S103, forming a dielectric layer by which the sensitive diaphragm and the plurality of interconnects are covered;

Step S104, forming a sensitive diaphragm support within the dielectric layer and on the surface of the sensitive diaphragm; and forming a conductive plug within the dielectric layer and on the surface of the interconnect;

Step S105, forming, on the surface of the dielectric layer, a sensitive diaphragm support arm, a fixed electrode corresponding to the sensitive diaphragm and a top-layer electrode, with the sensitive diaphragm support arm being coupled to the sensitive diaphragm support, and a plurality of through holes through the fixed electrode being formed within the fixed electrode;

Step S106, forming an opening within the substrate from the second surface, through which the sensitive diaphragm is exposed; and

Step S107, removing the dielectric layer corresponding to the opening to form a cavity.

More preferably, the sensitive diaphragm support may be located in the center of the sensitive diaphragm. Furthermore, a plurality of sensitive diaphragm supports may be provided, and the center of the plurality of sensitive diaphragm supports coincides with the center of the surface of the sensitive diaphragm.

In the MEMS microphone formed according to the embodiment of the present invention, a sensitive diaphragm support coupled to a sensitive diaphragm is formed on the surface of the sensitive diaphragm, and a sensitive diaphragm support arm coupled to the sensitive diaphragm support is formed, so as to replace the connection structures used in prior arts which is located at the edge of the diaphragm and made from the same material layer as the sensitive diaphragm. Since the diaphragm support positions are flexible and the influence of the stress on the sensitive diaphragm is small, the MEMS microphone of the present invention can be further miniaturized. Moreover, the sensitive diaphragm according to the present invention can achieve large vibration amplitude and higher sensitivity

Furthermore, the sensitive diaphragm support is located in the center of the sensitive diaphragm, or the center of the plurality of sensitive diaphragm supports coincides with the center of the surface of the sensitive diaphragm. Its influence on the vibration of the sensitive diaphragm outer area is reduced and the sensitivity of the MEMS microphone is improved.

### First Embodiment

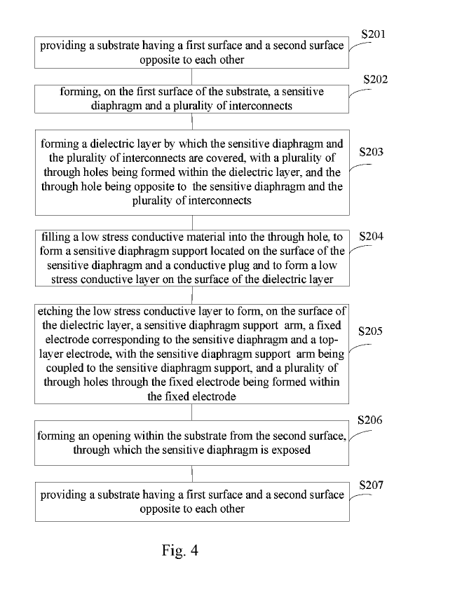

The method for forming the MEMS microphone of the present invention will be described in detail in conjunction with the first embodiment below. Referring to FIG. 4, which is a schematic flowchart of the method for forming the MEMS microphone according to the first embodiment, the method includes the following steps:

Step S201, providing a substrate having a first surface and a second surface opposite to each other;

Step S202, forming, on the first surface of the substrate, a sensitive diaphragm and a plurality of interconnects;

Step S203, forming a dielectric layer by which the sensitive diaphragm and the plurality of interconnects are covered, with a plurality of through holes being formed within the dielectric layer, and the position of the through hole being corresponding to that of the sensitive diaphragm and the plurality of interconnects;

Step S204, filling a low stress conductive material into the through hole, to form a sensitive diaphragm support located on the surface of the sensitive diaphragm and a conductive plug and to form a low stress conductive layer on the surface of the dielectric layer;

Step S205, etching the low stress conductive layer to form, on the surface of the dielectric layer, a sensitive diaphragm support arm, a fixed electrode corresponding to the sensitive diaphragm and a top-layer electrode, with the sensitive diaphragm support arm being coupled to the sensitive diaphragm support, and a plurality of through holes in the fixed electrode;

Step S206, forming an opening within the substrate from the second surface, through which the sensitive diaphragm is exposed; and

Step S207, removing the dielectric layer corresponding to the opening to form a cavity.

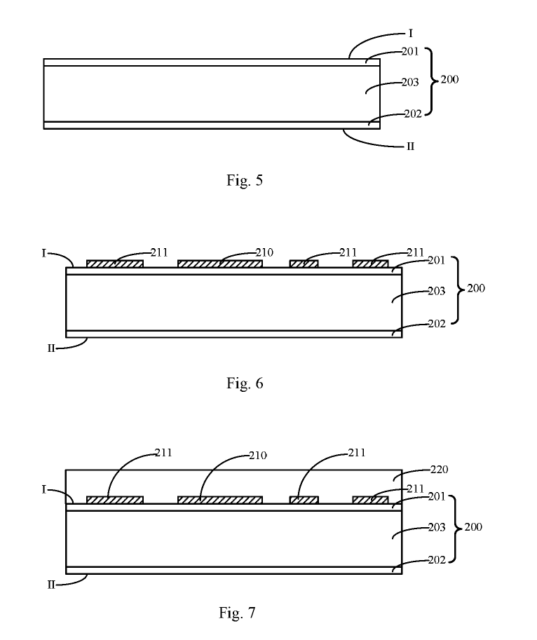

FIG. 5 to FIG. 13 are process diagrams of the method for forming the MEMS microphone according to the first embodiment of the present invention.

Referring to FIG. 5, a substrate 200 is provided by carrying out step S201. The substrate 200 has a first surface I and a second surface II opposite to each other.

The substrate 200 may be made from a semiconductor material, for example, the substrate 200 may be made from a single crystal semiconductor material such as single crystal silicon, single crystal germanium-silicon, single crystal GaAs, or single crystal GaN (e.g., a group II-VI compound semiconductor and a group III-V compound semiconductor). And the substrate 200 may also be a polycrystalline substrate or an amorphous substrate, for example, the substrate may be made from polycrystalline silicon or other materials. The material of the substrate 200 can be selected by those skilled in the art depending on the MEMS microphone to be formed. It should be noted specifically here that the scope of protection of the present invention should not be limited excessively.

It should also be noted that, to improve the performance of the MEMS microphone to be formed, the substrate 200 may also be a single layer structure or a multilayer stack structure, or the substrate 200 may also be a substrate in which a semiconductor device or other circuits such as a drive circuit and/or a signal processing circuit is formed. As one example of the present invention, the substrate 200 is a single crystal silicon substrate 203 having an upper surface on which an isolation layer 201 is formed and a lower surface on which an insulating layer 202 is formed. The first surface I of the substrate 200 is the upper surface of the isolation layer 201, and the second surface II of the substrate 200 is the lower surface of the insulating layer 202. The isolation layer 201 is adapted to isolate a sensitive diaphragm and a plurality of interconnects formed in the subsequent step, and the insulating layer 202 is adapted to prevent the substrate 200 from being damaged in the subsequent process.

The material of the isolation layer 201 and the insulating layer 202 may be silicon oxide, silicon nitride or silicon oxynitride. It should also be noted that, to improve the performance of the MEMS microphone, the isolation layer 201 and the insulating layer 202 may be a single structure or a multilayer stack structure. For example, the isolation layer 201 is a stack structure of silicon oxide and silicon nitride, and the insulating layer 202 is a stack structure of silicon oxide and silicon nitride. The process for forming the isolation layer 201 and the insulating layer 202 is a deposition process or a thermal oxidation process. In this embodiment, the material of the isolation layer 201 and the insulating layer 202 may be silicon oxide, and are formed by performing oxidation on the upper surface and the lower surface of the single crystal silicon substrate 203 by a thermal oxidation process. The thickness and the material of the isolation layer 201 and the insulating layer 202 may be selected by those skilled in the art depending on the MEMS microphone to be formed. It should be noted specifically here that the scope of protection of the present invention should not be limited excessively.

Referring to FIG. 6, a sensitive diaphragm 210 and a plurality of interconnects 211 are formed on the first surface I of the substrate 200 by carrying out step S202.

The sensitive diaphragm 210 is adapted to form a capacitor with a fixed electrode to be formed later. The sensitive diaphragm 210 may vibrate under the influence of an acoustic signal, and the acoustic signal will be converted into an electrical signal. The material of the sensitive diaphragm 210 is low stress polycrystalline silicon, and the sensitive diaphragm 210 may be square, circular or other shapes. A suitable shape of the sensitive diaphragm 210 may be selected by those skilled in the art depending on the MEMS microphone to be formed. It should be noted specifically here that the scope of protection of the present invention should not be limited excessively. It should also be noted here that since the sensitive diaphragm 210 is formed of the low stress polycrystalline silicon, the size and the production cost of the MEMS microphone adopting the sensitive diaphragm 210 can be further reduced.

The interconnect 211 is used as electrical interconnects for the sensitive diaphragm 210 of the MEMS microphone and the fixed electrode of the MEMS microphone, and to provide an electrical connection platform for a bonding pad to be formed later. The interconnect 211 is made from a conductive material. The position where the interconnect 211 is formed, and the number and the shape of the interconnect 211 may be determined depending on the specific MEMS microphone, and can be selected by those skilled in the art depending on the MEMS microphone to be formed. It should be noted specifically here that the scope of protection of the present invention should not be limited excessively.

It should also be noted that in this embodiment, the material of the interconnect 211 may be the same as that of the sensitive diaphragm 210, which is low stress polycrystalline silicon. Thus the interconnect 211 may be formed in the same deposition process and the same etching process as the sensitive diaphragm 210, so as to reduce number of some process steps.

The specific forming steps of the interconnect 211 and the sensitive diaphragm 210 are: depositing a low stress polycrystalline silicon thin film (not shown) on the first surface I of the substrate 200 by a chemical vapor deposition process; forming a photoresist layer (not shown) on the surface of the low stress polycrystalline silicon thin film; exposing and developing the photoresist layer using a mask corresponding to the interconnect 211 and the sensitive diaphragm 210, so as to form a photoresist pattern; and removing the low stress polycrystalline silicon thin film by a plasma etching process using the photoresist pattern as a mask, until the substrate 200 is exposed, so as to form the interconnect 211 and the sensitive diaphragm 210.

In the case where the material of the interconnect 211 is different from that of the sensitive diaphragm 210, a method in which the interconnect 211 is formed firstly and then the sensitive diaphragm 210 is formed, or another method in which the sensitive diaphragm 210 is formed firstly and then the interconnect 211 is formed, may be adopted, which will not be described in detail here.

It should also be noted that in order to improve the conductivity characteristic of the interconnect 211 and the sensitive diaphragm 210 and reduce the stress on the sensitive diaphragm 210, the low stress polycrystalline silicon thin film may also be doped after the low stress polycrystalline silicon thin film is formed, so as to reduce resistance of the interconnect 211 and the sensitive diaphragm 210, and the low stress polycrystalline silicon thin film may be annealed, so as to reduce the stress of the sensitive diaphragm 210. An ion implantation process or an in situ deposition and doping process may be used as the doping process, and a rapid annealing or a furnace annealing may be used as the annealing process.

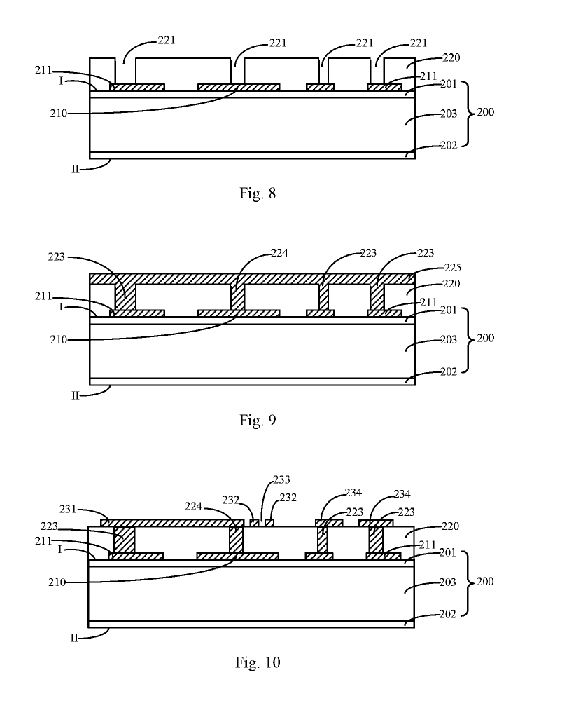

Referring to FIG. 7 and FIG. 8, by carrying out step S203, a dielectric layer 220 is formed, by which the sensitive diaphragm 210 and the plurality of interconnects 211 are covered, with a plurality of through holes 221 being formed within the dielectric layer 220, and the position of the through hole 221 being corresponding to a portion of the sensitive diaphragm 210 and the plurality of interconnects 211.

Referring to FIG. 7, the dielectric layer 220 is formed, by which the sensitive diaphragm 210 and the plurality of interconnects 211 are covered.

The dielectric layer 220 is made from a material which has a selective etching characteristic with respect to the sensitive diaphragm 210 and the interconnect 211. Specifically, the dielectric layer 220 is made from a dielectric material, such as silicon oxide or silicon oxynitride. In this embodiment, the dielectric layer 220 is made from silicon oxide.

The dielectric layer 220 is adapted to provide a work platform for a cavity of the MEMS microphone to be formed later, and to electrically isolate the interconnect 211 from a conductive electrode to be formed later.

The manufacturing process for the dielectric layer 220 is a deposition process, and is preferably a chemical vapor deposition process.

Referring to FIG. 8, the through hole 221 is formed within the dielectric layer 220, which has a position corresponding to a portion of the sensitive diaphragm 210 and the plurality of interconnects 211.

The through hole 221 is adapted to be filled with a material to form a sensitive diaphragm support and a conductive plug in the subsequent process step.

The specific steps of forming the through hole 221 are: forming a photoresist layer (not shown) on the surface of the dielectric layer 220; exposing and developing the photoresist layer using a mask corresponding to the through hole 221 so as to form a photoresist pattern; and removing the dielectric layer 220 by using the photoresist pattern as a mask, until the sensitive diaphragm 210 and the plurality of interconnects 211 are exposed, so as to form the through hole 221.

In this embodiment, preferably, the sensitive diaphragm support is located in the center of the sensitive diaphragm 210, i.e., the through hole corresponding to the sensitive diaphragm 210 is located in the center of the sensitive diaphragm 210. In the subsequent step, the through hole located in the center of the sensitive diaphragm 210 will be filled with a low stress material, so as to form the sensitive diaphragm support located in the center of the sensitive diaphragm 210.

Referring to FIG. 9, by carrying out step S204, a low stress conductive material is filled into the through hole 221, to form a sensitive diaphragm support 224 on the surface of the sensitive diaphragm 210 and a conductive plug 223 and to form a low stress conductive layer 225 on the surface of the dielectric layer 220.

It should be noted that in this step, the sensitive diaphragm support 224, the conductive plug 223 and the low stress conductive layer 225 are formed concurrently by a deposition process. The low stress conductive layer 225 will be etched in the subsequent step so as to form a sensitive diaphragm support arm, a fixed electrode and a top-layer electrode, thereby process steps can be simplified and a production cost can be reduced.

In this embodiment, the material of the sensitive diaphragm support 224 is the same as that of the sensitive diaphragm support arm, the fixed electrode and the top-layer electrode, which is a low stress conductive material, such as a polycrystalline silicon material.

The filling of the low stress conductive material and the forming of the low stress conductive layer 225 are carried out in the same deposition process, such as a low pressure chemical vapor deposition, a plasma-assisted enhanced vapor deposition process or an atomic layer stack deposition. The deposition process can be selected by those skilled in the art depending on a specific size of the through hole 221, which will not be described in detail here.

In this embodiment, the sensitive diaphragm support 224 is located in the center of the surface of the sensitive diaphragm 210, so that the interference of the sensitive diaphragm support 224 on the vibration of the sensitive diaphragm 210 can be reduced when the sensitive diaphragm 210 is sensing an acoustic signal, thereby the sensitivity of the MEMS microphone of the prevent invention will be improved.

Referring to FIG. 10, by carrying out step S205, the low stress conductive layer 225 is etched to form, on the surface of the dielectric layer 220, a sensitive diaphragm support arm 231, a fixed electrode 232 corresponding to the sensitive diaphragm 210 and a top-layer electrode 234, with the sensitive diaphragm support arm 231 being coupled to the sensitive diaphragm support 224, and a plurality of through holes in the fixed electrode 232 being formed within the fixed electrode 232.

The specific forming steps are: forming a photoresist layer on the surface of the low stress conductive layer 225; exposing and developing the photoresist layer using a mask corresponding to the sensitive diaphragm support arm 231, the fixed electrode 232 and the top-layer electrode 234, so as to form a photoresist pattern; and etching the polycrystalline silicon thin film by using the photoresist pattern as a mask, so as to form the sensitive diaphragm support arm 231, the fixed electrode 232 and the top-layer electrode 234, with the sensitive diaphragm support arm 231 being coupled to the sensitive diaphragm support 224, and a plurality of through holes 233 in the fixed electrode 232 being formed within the fixed electrode 232; and removing the photoresist pattern.

In this embodiment, since the edge of the sensitive diaphragm 210 is free completely and has no connection component, and the sensitive diaphragm support 224 is made from polycrystalline silicon which is a conductive material in this embodiment, the sensitive diaphragm support arm 231 is electrically coupled to the sensitive diaphragm support 224, so that the acoustic signal sensed by the sensitive diaphragm 210 is transmitted to an external system. In the structure described above, not only the edge of the sensitive diaphragm 210 is free completely and the stress is reduced, but also the signal of the sensitive diaphragm 210 can be transmitted to other systems.

The fixed electrode 232 is adapted to form a capacitor with the sensitive diaphragm 210 formed previously, and the acoustic signal sensed by the capacitor is converted into an electrical signal.

The through hole 233 is formed in the fixed electrodes 232. The through hole 233 is adapted to pass an acoustic signal, so that the acoustic signal is able to pass through the fixed electrode 232 without being isolated, therefore the acoustic signal can be sensed by the sensitive diaphragm 210.

In this embodiment, the top-layer electrode 234 may serve as a platform for supporting the bonding pad, and serve as a lead for electrical connection of the fixed electrode 232 or the sensitive diaphragm support arm 231. The layout distribution and the shape of the top-layer electrode 234 can be selected by those skilled in the art depending on a specific design of the MEMS microphone. It should be noted specifically here that the scope of protection of the present invention should not be limited excessively.

It should also be noted that in this embodiment, the top-layer electrode 234 is formed in the same deposition process and the same etching process as the sensitive diaphragm support arm 231 and the fixed electrode 232. In other embodiments, a metal layer may be further deposited by an additional metal deposition process, and the metal layer is etched to form the top-layer electrode. It should be noted specifically here that the top-layer metal may also be used to form bonding pad directly, and no additional process and step of forming the bonding pad is needed.

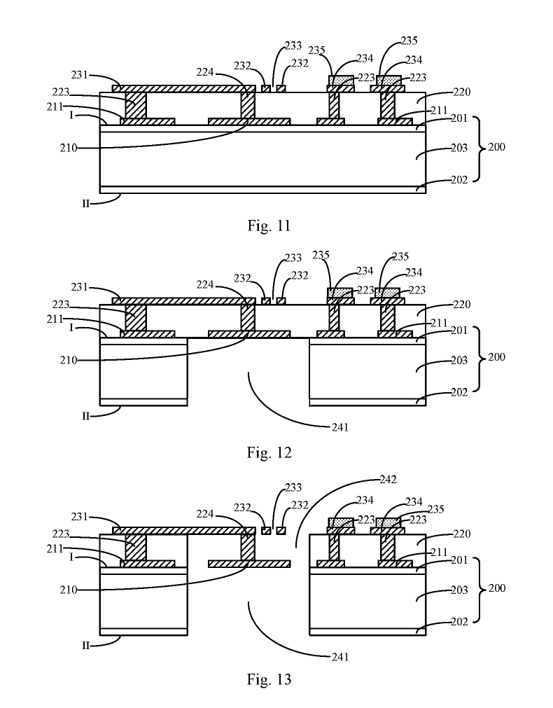

Referring to FIG. 11, it should be noted that the MEMS microphone transmits the acoustic signal which is sensed by the sensitive diaphragm 210 to other circuits, so as to process the transmitted signal. Generally, the top-layer electrode is electrically coupled to a circuit for processing the signal by a wire-bonding technology. Specifically, a metal wire, for example, gold wire, aluminum wire or copper wire, is usually used in the wire-bonding technology to provide the electrical coupling. In this embodiment, the top-layer electrode 234 is made from polycrystalline silicon, and the adhesion property between the metal wire and polycrystalline silicon is poor. Therefore, in order to facilitate the transmission of the signal of the MEMS microphone, a bonding pad 235 will be generally further formed on the surface of the top-layer electrode 234. Specifically, the bonding pad 235 is made from metal, and the bonding pad 235 is used to provide an electrical connection platform for the MEMS microphone.

A manufacturing process for the bonding pad 235 may be such a process in which a metal layer (not shown) is deposited by a physical vapor deposition, and the metal layer is photolithographically patterned and is etched to form the bonding pad 235. A specific forming step of the bonding pad 235 can be determined by those skilled in the art depending on the specific requirement of the MEMS microphone and referring to existing forming methods of bonding pad. It should also be noted that the bonding pad 235 may be formed in any step after the top-layer electrode 234 is formed and not limited to be formed in this step, and the bonding pad 235 may also be formed before or after step S206, or before step S207. It should be noted specifically here that the scope of protection of the present invention should not be limited excessively.

Practically, in other embodiments of the present invention, if the top-layer electrode 234 is made from other materials, such as metal, the top-layer electrode 234 may be used to form bonding pad directly, and no additional step of forming the bonding pad is needed.

Referring to FIG. 12, by carrying out step S206, an opening 241 is formed within the substrate from the second surface II, through which the sensitive diaphragm 210 is exposed.

The manufacturing process for the opening 241 is an etching process, and specifically, may be a wet etching or a dry etching.

Specifically, the manufacturing process for the opening 241 includes: forming, on the second surface II, a photoresist pattern corresponding to the opening 241; and etching the substrate 200 by using the photoresist pattern as a mask, until the sensitive diaphragm 210 is exposed, so as to form the opening 241.

The opening 241 is adapted to constitute a part of a cavity, thus the sensitive diaphragm 210 is released, so that the sensitive diaphragm 210 is able to vibrate within the cavity when an acoustic signal is sensed by the sensitive diaphragm 210, and the acoustic signal is converted into an electrical signal.

Referring to FIG. 13, by carrying out step S207, the dielectric layer 220 corresponding to the opening 241 is removed to form a cavity 242.

The material of the dielectric layer 220 formed in the step S203 is a material which has a selective etching characteristic with respect to the sensitive diaphragm 210 and the interconnect 211. In this step, the dielectric layer 220 corresponding to the opening 241 can be removed without damaging the sensitive diaphragm 210, the interconnect 211, the sensitive diaphragm support 224 and the conductive plug 223, as long as the etching process has a high etching selectivity ratio with respect to the dielectric layer 220.

The etching process may be a wet etching or a dry etching.

It should be noted that when removing the dielectric layer 220 corresponding to the opening 241, the dielectric layer 220 may be removed from two sides of the opening 241 and the though hole 233, so that the dielectric layer 220 will be removed faster.

In the method for forming MEMS microphone according to the first embodiment of the present invention, the sensitive diaphragm support 224, the conductive plug 223 and the low stress conductive layer 225 are formed at one time by a deposition process. The low stress conductive layer 225 will be etched in the subsequent step so as to form the sensitive diaphragm support arm, the fixed electrode and the top-layer electrode, thereby some process steps can be simplified and a production cost will be reduced.

Referring to FIG. 13, the MEMS microphone which is formed by the method for forming the MEMS microphone according to the first embodiment of the present invention includes: a substrate 200 having a first surface I and a second surface II; an opening 241 through the substrate 200; a plurality of interconnects 211 formed on the first surface of the substrate; a dielectric layer 220 which is formed on the first surface of the substrate and by which the plurality of interconnects 211 are covered; a conductive plug 223 formed within the dielectric layer 220 and electrically coupled to the interconnect 211; a cavity 242 located within the dielectric layer 220 and in communication with the opening; a sensitive diaphragm 210 located within the cavity; a sensitive diaphragm support 224 located on the surface of the sensitive diaphragm 210; a sensitive diaphragm support arm 231 partly located on the surface of the dielectric layer 220 and coupled to the sensitive diaphragm support 224; a fixed electrode 232 corresponding to the sensitive diaphragm 210, within which a plurality of through holes 233 through the fixed electrode 232 are formed; and a top-layer electrode 234 electrically coupled to the conductive plug 223.

The material of the sensitive diaphragm support 224 is the same as that of the sensitive diaphragm support arm 231, such as polycrystalline silicon.

Furthermore, the sensitive diaphragm support 224 is located in the center of the surface of the sensitive diaphragm 210.

In the MEMS microphone formed according to the first embodiment of the present invention, a structure including a sensitive diaphragm support 224 located in the center of the surface of a sensitive diaphragm 210 and a sensitive diaphragm support arm 231 is adopted. The edge of the sensitive diaphragm 210 is free, so that the influence of the external variables on the stress of the sensitive diaphragm is small, and thereby the sensitivity of the MEMS microphone is improved. The size and the production cost of the MEMS microphone of the present invention can be further reduced because there is no stress influence on the MEMS microphone.

### Second Embodiment

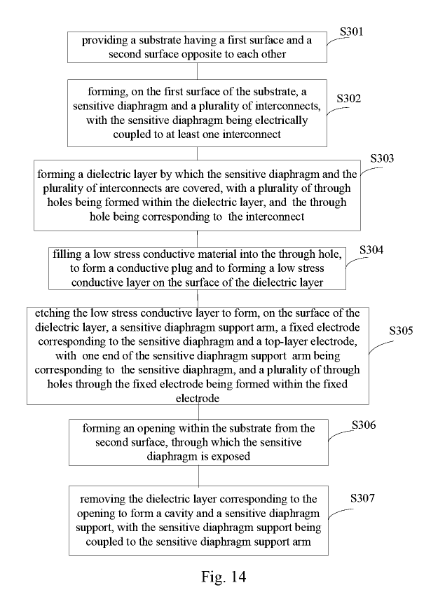

The method for forming the MEMS microphone of the present invention will be described in detail in conjunction with the second embodiment below. Referring to FIG. 14, which is a schematic flowchart of the method for forming the MEMS microphone according to the second embodiment, the method includes the following steps:

Step S301, providing a substrate having a first surface and a second surface opposite to each other;

Step S302, forming, on the first surface of the substrate, a sensitive diaphragm and a plurality of interconnects, with the sensitive diaphragm being electrically coupled to at least one interconnect;

Step S303, forming a dielectric layer by which the sensitive diaphragm and the plurality of interconnects are covered, with a plurality of through holes being formed within the dielectric layer, and the position of the through hole being corresponding to that of the interconnect;

Step S304, filling a low stress conductive material into the through hole to form a conductive plug and forming a low stress conductive layer on the surface of the dielectric layer;

Step S305, etching the low stress conductive layer to form, on the surface of the dielectric layer, a sensitive diaphragm support arm, a fixed electrode corresponding to the sensitive diaphragm and a top-layer electrode, with the position of one end of the sensitive diaphragm support arm being corresponding to that of the sensitive diaphragm, and a plurality of through holes through the fixed electrode being formed within the fixed electrode;

Step S306, forming an opening within the substrate from the second surface, through which the sensitive diaphragm is exposed; and

Step S307, removing the dielectric layer corresponding to the opening to form a cavity and a sensitive diaphragm support, with the sensitive diaphragm support being coupled to the sensitive diaphragm support arm.

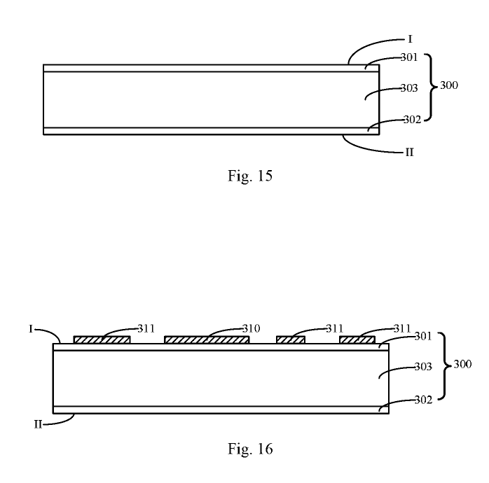

FIG. 15 to FIG. 24 are process diagrams of the method for forming the MEMS microphone according to the second embodiment of the present invention.

Referring to FIG. 15 and FIG. 14, by carrying out step S301, a substrate 300 is provided, which has a first surface I and a second surface II opposite to each other.

The substrate 300 may be made from a semiconductor material, for example, the substrate 300 may be made from a single crystal semiconductor material such as single crystal silicon or single crystal germanium-silicon (e.g., a group II-VI compound semiconductor and a group III-V compound semiconductor). The substrate 300 may also be a polycrystalline substrate or an amorphous substrate, for example, the substrate may be made from polycrystalline silicon or other materials. The material of the substrate 300 can be selected by those skilled in the art depending on the MEMS microphone to be formed. It should be noted specifically here that the scope of protection of the present invention should not be limited excessively.

It should also be noted that, in order to improve the performance of the MEMS microphone to be formed, the substrate 300 may also be a single layer structure or a multilayer stack structure, or the substrate 300 may also be a substrate in which a semiconductor device or other circuits such as a drive circuit and/or a signal processing circuit is formed. As one example of the present invention, the substrate 300 is a single crystal silicon substrate 303 having an upper surface on which an isolation layer 301 is formed and a lower surface on which an insulating layer 302 is formed. The first surface I of the substrate 300 is the upper surface of the isolation layer 301, and the second surface II of the substrate 300 is the lower surface of the insulating layer 302. The isolation layer 301 is adapted to isolate a sensitive diaphragm and a plurality of interconnects formed in the subsequent step, and the insulating layer 302 is adapted to prevent the substrate 300 from being damaged in the subsequent process.

The material of the isolation layer 301 and the insulating layer 302 may be silicon oxide, silicon nitride or silicon oxynitride. It should also be noted that, in order to improve the performance of the MEMS microphone to be formed, the isolation layer 301 and the insulating layer 302 may be a single layer structure or a multilayer stack structure. For example, the isolation layer 301 is a stack structure of silicon oxide and silicon nitride, and the insulating layer 302 is a stack structure of silicon oxide and silicon nitride. The process for forming the isolation layer 301 and the insulating layer 302 is a deposition process or a thermal oxidation process. In this embodiment, the material of the isolation layer 301 and the insulating layer 302 may be silicon oxide, and are formed by performing oxidation on the upper surface and the lower surface of the single crystal silicon substrate 303 by a thermal oxidation process. The thickness and the material of the isolation layer 301 and the insulating layer 302 may be selected by those skilled in the art depending on the MEMS microphone to be formed. It should be noted specifically here that the scope of protection of the present invention should not be limited excessively.

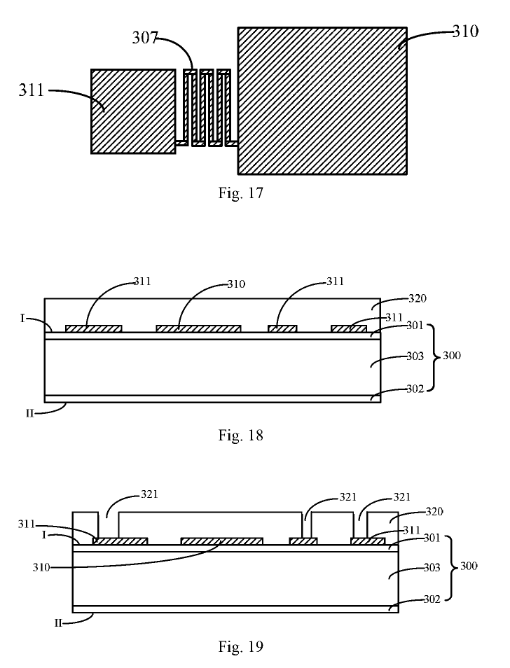

Referring to FIG. 16, by carrying out S302, a sensitive diaphragm 310 and a plurality of interconnects 311 are formed on the first surface I of the substrate 300, with the sensitive diaphragm 310 being electrically coupled to at least one interconnect 311.

The sensitive diaphragm 310 is adapted to form a capacitor with a fixed electrode to be formed later. The sensitive diaphragm 310 may vibrate under the influence of an acoustic signal, and the acoustic signal will be converted into an electrical signal. The material of the sensitive diaphragm 310 is low stress polycrystalline silicon, and the sensitive diaphragm 310 may be square, circular or other shapes. A suitable shape of the sensitive diaphragm 310 may be selected by those skilled in the art depending on the MEMS microphone to be formed. It should be noted specifically here that the scope of protection of the present invention should not be limited excessively. It should also be noted here that the sensitive diaphragm 310 is made from low stress polycrystalline silicon, the size and the production cost of the MEMS microphone adopting the sensitive diaphragm 310 can be reduced.

The interconnect 311 is adapted to electrically couple the sensitive diaphragm 310 of the MEMS microphone to a fixed electrode of the MEMS microphone. The interconnect 311 is made from a conductive material. The position where the interconnect 311 is formed, the number and the shape of the interconnect 311 may be determined depending on the specific MEMS microphone, and can be selected by those skilled in the art depending on the MEMS microphone to be formed. It should be noted specifically here that the scope of protection of the present invention should not be limited excessively.

It should also be noted that in this embodiment, the material of the interconnect 311 may be the same as that of the sensitive diaphragm 310, which is low stress polycrystalline silicon. Thus the interconnect 311 may be formed in the same deposition process and the same etching process as the sensitive diaphragm 310, so as to eliminate some process steps.

The specific steps of forming the interconnect 311 and the sensitive diaphragm 310 are: depositing a low stress polycrystalline silicon thin film (not shown) on the first surface I of the substrate 300 by a chemical vapor deposition process; forming a photoresist layer (not shown) on the surface of the low stress polycrystalline silicon thin film; exposing and developing the photoresist layer using a mask corresponding to the interconnect 311 and the sensitive diaphragm 310 so as to form a photoresist pattern; and removing the low stress polycrystalline silicon thin film by a plasma etching process by using the photoresist pattern as a mask, until the substrate 300 is exposed, so as to form the interconnect 311 and the sensitive diaphragm 310.

In the case where the material of the interconnect 311 is different from that of the sensitive diaphragm 310, a forming method in which the interconnect 311 is formed firstly and then the sensitive diaphragm 310 is formed, or another forming method in which the sensitive diaphragm 310 is formed firstly and then the interconnect 311 is formed, may be adopted, which will not be described in detail here.

It should also be noted that in order to improve the conductivity characteristic of the interconnect 311 and the sensitive diaphragm 310 and reduce the stress on the sensitive diaphragm 310, the low stress polycrystalline silicon thin film may also be doped after the low stress polycrystalline silicon thin film is formed so as to reduce the resistance of the interconnect 311 and the sensitive diaphragm 310, and the low stress polycrystalline silicon thin film may be annealed so as to reduce the stress on the sensitive diaphragm 310. An ion implantation process or an in situ deposition and doping process may be used as the doping process, and a rapid annealing or a furnace annealing may be used as the annealing process.

Referring to FIG. 17, in this embodiment, the material of a sensitive diaphragm support to be formed later is the same as that of the dielectric layer, which is an insulation material. The sensitive diaphragm 310 will further need to be electrically coupled to at least one interconnect 311 via a sensitive diaphragm connection structure 307 so that the acoustic signal sensed by the sensitive diaphragm 310 can be transmitted.

The sensitive diaphragm connection structure 307 is made from a flexible conductive material, such as polycrystalline silicon. The sensitive diaphragm connection structure 307 is for example an S-shape, a Z-shape or other curve shapes. The shape and the material of sensitive diaphragm connection structure 307 is selected based on that its influence on the vibration of the sensitive diaphragm 310 is small.

Referring to FIG. 18 and FIG. 19, by carrying out step S303, a dielectric layer 320 is formed, by which the sensitive diaphragm 310 and the plurality of interconnects 311 are covered, with a plurality of through holes 321 being formed within the dielectric layer 320, and the through hole 321 being corresponding to the interconnect 311.

Referring to FIG. 18, the dielectric layer 320 is formed, by which the sensitive diaphragm 310 and the plurality of interconnects 311 are covered.

The dielectric layer 320 is made from a material which has a selective etching characteristic with respect to the sensitive diaphragm 310 and the interconnect 311. Specifically, the dielectric layer 320 is made from silicon oxide.

The dielectric layer 320 is adapted to provide a work platform for a cavity of the MEMS microphone to be formed later, and to electrically isolate the interconnect 311 from a conductive electrode to be formed later. It should also be noted that the dielectric layer 320 in this embodiment is also adapted to form a sensitive diaphragm support as well.

The manufacturing process for the dielectric layer 320 is a deposition process, and is preferably a chemical vapor deposition process.

Referring to FIG. 19, the through hole 321 is formed within the dielectric layer 320, which has a position corresponding to that of the plurality of interconnects 311.

The through hole 321 is adapted to be filled with a conductive material to form a conductive plug in the subsequent process step.

The specific steps of forming the through hole 321 are: forming a photoresist layer (not shown) on the surface of the dielectric layer 320; exposing and developing the photoresist layer using a mask corresponding to the through hole 321 so as to form a photoresist pattern; and removing the dielectric layer 320 by using the photoresist pattern as a mask, until the plurality of interconnects 311 are exposed, so as to form the through hole 321.

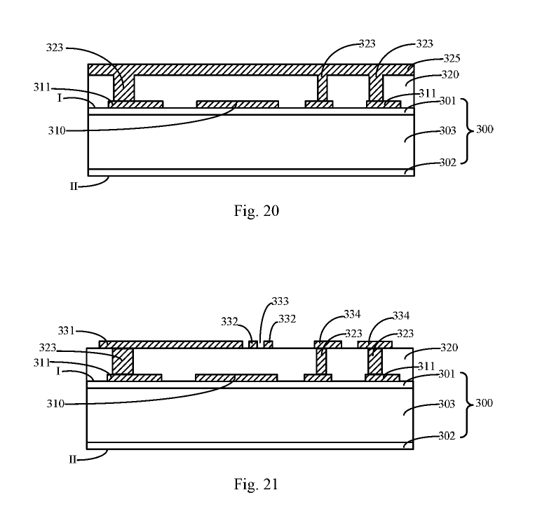

Referring to FIG. 20, by carrying out step S304, a low stress conductive material is filled into the through hole to form a conductive plug 323 and forming a low stress conductive layer on the surface of the dielectric layer.

It should be noted that in this step, the conductive plug 323 and the low stress conductive layer 325 are formed at one time by a deposition process. The low stress conductive layer 325 will be etched in the subsequent step so as to form the sensitive diaphragm support arm, the fixed electrode and the top-layer electrode, thereby process steps can be simplified and a production cost will be reduced.

The filling of the low stress conductive material and the forming of the low stress conductive layer 325 are carried out in the same deposition process, such as a sub-atmospheric pressure chemical vapor deposition, a plasma-assisted enhanced vapor deposition process or an atomiclayer stack deposition. The deposition process can be selected by those skilled in the art depending on a specific size of the through hole 321, which will not be described in detail here.

Referring to FIG. 21, by carrying out step S305, the low stress conductive layer 325 is etched to form, on the surface of the dielectric layer 320, a sensitive diaphragm support arm 331, a fixed electrode 310 corresponding to the sensitive diaphragm 310 and a top-layer electrode 334, with the position of one end of the sensitive diaphragm support arm 331 being corresponding to that of the sensitive diaphragm 310, and a plurality of through holes 333 through the fixed electrode 332 being formed within the fixed electrode 332.

The specific forming steps are: forming a photoresist layer on the surface of the low stress conductive layer 325; exposing and developing the photoresist layer using a mask corresponding to the sensitive diaphragm support arm 331, the fixed electrode 332 and the top-layer electrode 334 so as to form a photoresist pattern; and etching the polycrystalline silicon thin film by using the photoresist pattern as a mask, so as to form the sensitive diaphragm support arm 331, the fixed electrode 332 and the top-layer electrode 334, with a plurality of through holes 333 through the fixed electrode 332 being formed within the fixed electrode 332; and removing the photoresist pattern.

The fixed electrode 332 is adapted to form a capacitor with the sensitive diaphragm 310 formed previously, and the acoustic signal sensed by the capacitor is converted into an electrical signal.

The through hole 333 through the fixed electrode 332 is formed in the fixed electrodes 332. The through hole 333 is adapted to pass an acoustic signal, so that the acoustic signal is able to pass through the fixed electrode 332 without being isolated, therefore the acoustic signal can be sensed by the sensitive diaphragm 310.

The position of one end of the sensitive diaphragm support arm 331 is corresponding to that of the sensitive diaphragm 310. The area of the one end of the sensitive diaphragm support arm 331 which has a position corresponding to the position of the sensitive diaphragm 310 is larger than the area of the fixed electrode 332 between two adjacent through holes 333, so that in the subsequent step of removing the dielectric layer 320 to form a cavity, the dielectric layer 320 below one end of the sensitive diaphragm support arm 331 which has a position corresponding to the position of the sensitive diaphragm 310 will be retained partially rather than be removed entirely, so as to form a sensitive diaphragm support.

In this embodiment, the sensitive diaphragm support arm 331 is a single arm, and the exemplary description is given by taking the instance in which the position of one end of the sensitive diaphragm support arm 331 is corresponding to the position of the sensitive diaphragm 310. It should be noted that the performance of the MEMS microphone will not be influenced by the correspondence between the position of any part of the sensitive diaphragm support arm 331 and the position of the sensitive diaphragm 310. The portion of the sensitive diaphragm support arm 331 which corresponds to the position of the sensitive diaphragm 310 can be selected by those skilled in the art depending on actual need. It should be noted specifically here that the scope of protection of the present invention should not be limited excessively.

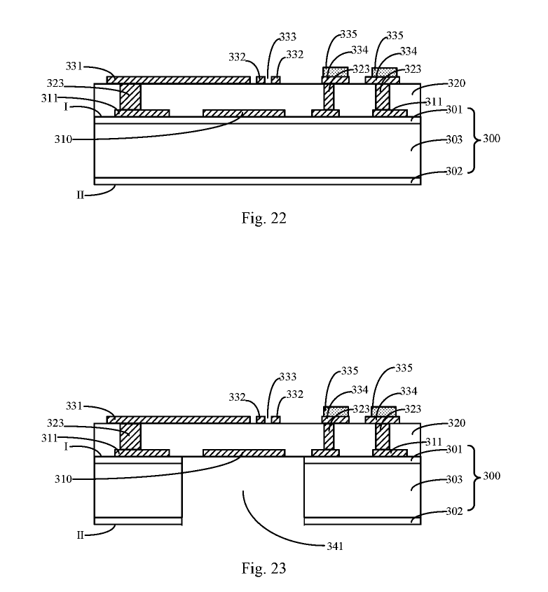

In other embodiments, for example, in which the sensitive diaphragm support arm 331 is a crossing-over arm, the position of a portion of the sensitive diaphragm support arm 331 needs to be corresponding to the position of the sensitive diaphragm 310. It should also be noted here that the shape and structure of the sensitive diaphragm support arm 331 and the portion of the sensitive diaphragm support arm 331 which corresponds to the position of the sensitive diaphragm 310 can be selected by those skilled in the art depending on actual need. It should be noted specifically here that the scope of protection of the present invention should not be limited excessively. Referring to FIG. 22, it should be noted that the acoustic signal sensed by the sensitive diaphragm 310 needs to be transmitted to other circuits by the MEMS microphone so as to process the transmitted signal. Generally, a top-layer electrode is electrically coupled to a circuit for processing the signal by a wire-bonding technology. Specifically, a metal wire, for example, gold wire, aluminum wire or copper wire, is usually used in the wire-bonding technology to provide the electrical connection. In this embodiment, the top-layer electrode 334 is made from polycrystalline silicon, and the adhesion property between the metal wire and polycrystalline silicon is poor. Therefore a bonding pad 335 is generally further formed on the surface of the top-layer electrode 334, in order to facilitate the transmission of the signal of the MEMS microphone. Specifically, the bonding pad 335 is made from metal, and the bonding pad 335 is used to provide an electrical connection platform for the MEMS microphone.

A manufacturing process for the bonding pad 235 may be such a process in which a metal layer (not shown) is deposited by a physical vapor deposition, and the metal layer is photoresist patterned and is etched to form the bonding pad 235. A specific forming step of the bonding pad 335 can be determined by those skilled in the art depending on the specific requirement of the MEMS microphone and referring to the existing techniques of forming bonding pad. It should also be noted that the bonding pad 335 may be formed in any step after the top-layer electrode 334 is formed, and not limited to be formed in this step, and the bonding pad 335 may be formed before or after step S306, or before step S307. It should be noted specifically here that the scope of protection of the present invention should not be limited excessively.

Practically, in other embodiments of the present invention, if the top-layer electrode 334 is made from other materials, such as metal, the top-layer electrode 334 may serve as a bonding pad directly, and no additional step of forming the bonding pad is needed.

Referring to FIG. 23, by carrying out step S306, an opening 341 is formed in the substrate 300 from the second surface II, through which the sensitive diaphragm is exposed.

The manufacturing process for the opening 341 is an etching process, and specifically, may be a wet etching or a dry etching.

On the second surface II, a photoresist pattern corresponding to the opening 341 is formed; and, by using the photoresist pattern as a mask, the substrate 300 is etched, until the sensitive diaphragm 310 is exposed, so as to form the opening 341.

The opening 341 is adapted to constitute a part of a cavity, thus the sensitive diaphragm 310 is released, so that the sensitive diaphragm 310 is able to vibrate within the cavity when an acoustic signal is sensed by the sensitive diaphragm 310, and the acoustic signal is converted into an electrical signal.

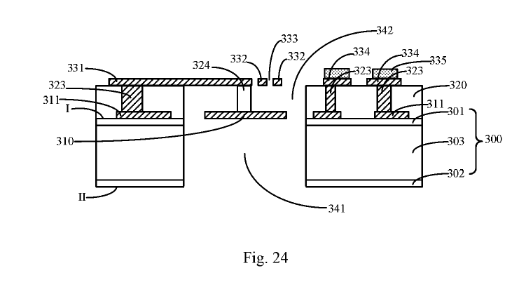

Referring to FIG. 24, by carrying out step S307, the dielectric layer 320 corresponding to the opening 341 is removed to form a cavity 342 and a sensitive diaphragm support 324, with the sensitive diaphragm support 324 being coupled to the sensitive diaphragm support arm 331.

The material of the dielectric layer 320 formed in the step S303 is a material which has a selective etching characteristic with respect to the sensitive diaphragm 310 and the interconnect 311. In this step, the dielectric layer 320 corresponding to the opening 341 can be removed without damaging the sensitive diaphragm 310, the interconnect 311 and the conductive plug 323, as long as the etching process has a high etching selectivity ratio with respect to the dielectric layer 320.

The etching process may be a dry etching or a wet etching.

It should be noted that the sensitive diaphragm support arm 331 formed in the step S305 has a portion which corresponds to the position of the sensitive diaphragm 310, and the area of the portion of the sensitive diaphragm support arm 331 which has a position corresponding to the position of the sensitive diaphragm 310 is larger than the area of the fixed electrode 332 between two adjacent through holes 333, so that in the step of removing the dielectric layer 320 to form a cavity, the dielectric layer 320 below the portion of the sensitive diaphragm support arm 331 which has a position corresponding to the position of the sensitive diaphragm 310 will be retained partially rather than be removed entirely, so as to form the sensitive diaphragm support 324. It should also be noted that in this embodiment, the sensitive diaphragm support 324 is preferably located in the center of the sensitive diaphragm 310. The formed sensitive diaphragm support 324 is located in the center of the sensitive diaphragm 310 by means of controlling the area of the fixed electrode 332 between two adjacent through holes 333 and the area of the one end of the sensitive diaphragm support arm 331 which has a position corresponding to the position of the sensitive diaphragm 310. The sensitive diaphragm support 324 is located in the center of the sensitive diaphragm 310 and has little influence on the vibration of the sensitive diaphragm 310.

In the method for forming MEMS microphone according to the second embodiment of the present embodiment, the sensitive diaphragm support 324 located in the center of the sensitive diaphragm 310 is formed while the cavity is formed by etching the dielectric layer 320, no additional process step is needed to form the sensitive diaphragm support 324, thereby process steps are simplified and production cost is reduced.

Referring to FIG. 24, the MEMS microphone formed by the method for forming the MEMS microphone according to the second embodiment of the present invention includes: a substrate 300 having a first surface I and a second surface II; an opening 341 through the substrate 300; a plurality of interconnects 311 formed on the first surface of the substrate; a dielectric layer 320 which is formed on the first surface of the substrate and by which the plurality of interconnects 311 are covered; a conductive plug 323 formed within the dielectric layer 320 and electrically coupled to the interconnect 311; a cavity 342 located in the dielectric layer 320 and in communication with the opening; a sensitive diaphragm 310 located within the cavity, which is electrically coupled to at least one interconnect 311 via a sensitive diaphragm connection structure 370; a sensitive diaphragm support 324 located in the center of the surface of the sensitive diaphragm 310; a sensitive diaphragm support arm 331 partly located on the surface of the dielectric layer 320 and coupled to the sensitive diaphragm support 324; a fixed electrode 332 corresponding to the sensitive diaphragm 310, within which a plurality of through holes 333 through the fixed electrode 332 are formed; and a top-layer electrode 334 electrically coupled to a conductive plug 323.

The material of a sensitive diaphragm support 324 is the same as that of a dielectric layer 320, such as silicon oxide.

In the MEMS microphone formed according to the second embodiment of the present invention, a structure including a sensitive diaphragm support 324 located in the center of the surface of a sensitive diaphragm 310 and a sensitive diaphragm support arm 331 is adopted. The sensitive diaphragm 310 is electrically coupled to at least one interconnect 311 via a sensitive diaphragm connection structure 370 which is made from a flexible conductive material, so that the influence of the external variables on the stress of the sensitive diaphragm is small, and thereby the sensitivity of the MEMS microphone will be maintained. The size and the production cost of the MEMS microphone of the present invention can be reduced because there is no stress influence on the MEMS microphone.

### Third Embodiment

It has been noted by the inventor of the present invention that the existing MEMS microphone is widely used in small electronic devices such as mobile phones, and the small electronic devices are easy to collide or drop, and in this case, a sensitive diaphragm of the MEMS microphone tends to come into contact with a fixed electrode which has a position corresponding to that of the sensitive diaphragm. Because the surfaces of the sensitive diaphragm and the fixed electrode are smooth and are charged with opposite charges, the sensitive diaphragm and the fixed electrode tend to stick to each other in the case where the sensitive diaphragm comes into contact with the fixed electrode, due to forces such as the Van der Waals' force. It is difficult to separate the stuck sensitive diaphragm and the fixed electrode, resulting in failure of the MEMS microphone.

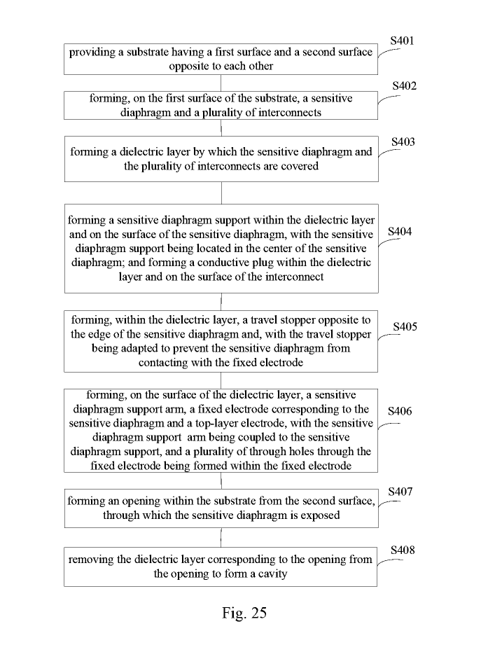

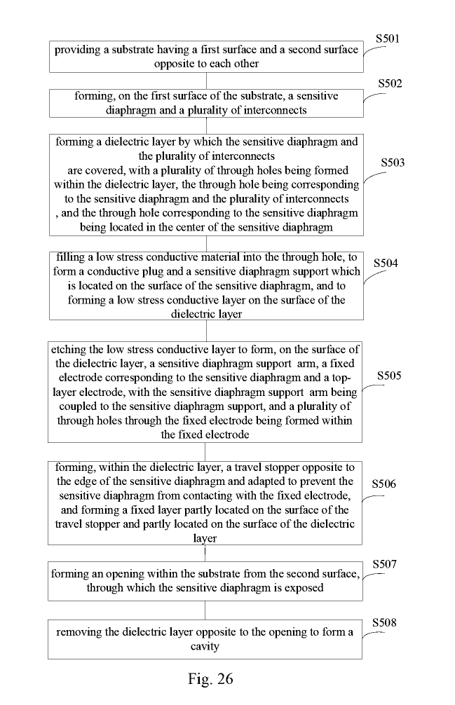

To this end, an optimized method for forming a MEMS microphone is proposed by the inventor of the present invention. The method for forming the MEMS microphone of the present invention will be described in detail in conjunction with the third embodiment below. Referring to FIG. 25, which is a schematic flowchart of the method for forming the MEMS microphone according to the third embodiment, the method includes the following steps:

Step S401, providing a substrate having a first surface and a second surface opposite to each other;

Step S402, forming, on the first surface of the substrate, a sensitive diaphragm and a plurality of interconnects;

Step S403, forming a dielectric layer by which the sensitive diaphragm and the plurality of interconnects are covered;

Step S404, forming a sensitive diaphragm support within the dielectric layer and on the surface of the sensitive diaphragm, with the sensitive diaphragm support being located in the center of the sensitive diaphragm; and forming a conductive plug within the dielectric layer and on the surface of the interconnect;

Step S405, forming, within the dielectric layer, a travel stopper corresponding to the edge area of the sensitive diaphragm, with the travel stopper being used to prevent the sensitive diaphragm from contacting the fixed electrode;

Step S406, forming, on the surface of the dielectric layer, a sensitive diaphragm support arm, a fixed electrode corresponding to the sensitive diaphragm and a top-layer electrode, with the sensitive diaphragm support arm being coupled to the sensitive diaphragm support, and a plurality of through holes through the fixed electrode being formed within the fixed electrode;

Step S407, forming an opening within the substrate from the second surface, through which the sensitive diaphragm is exposed; and

Step S408, removing the dielectric layer corresponding to the opening from the opening to form a cavity.

It should be noted that in the third embodiment, the sensitive diaphragm support may be formed in two manners. A first manner is that the sensitive diaphragm support is formed as in the first embodiment, i.e., the material of the sensitive diaphragm support is consistent with that of the sensitive diaphragm support arm, the material of the fixed layer and the material of the top-layer electrode. A second manner is that the sensitive diaphragm support is formed as in the second embodiment, i.e., the material of the sensitive diaphragm support is consistent with that of the dielectric layer.

In the third embodiment of the present invention, the travel stopper corresponding to the edge area of the sensitive diaphragm and used to block the vibrating sensitive diaphragm is formed within the dielectric layer. The travel stopper can prevent the sensitive diaphragm from contacting the fixed electrode during the process of collision or drop of the MEMS microphone, thereby can prevent the sensitive diaphragm and the fixed electrode from being stuck to each other.

### Fourth Embodiment

An optimized method for forming a MEMS microphone is proposed by the inventor of the present invention. The method for forming the MEMS microphone of the present invention will be described in detail in conjunction with the fourth embodiment below. Referring to FIG. 26, which is a schematic flowchart of the method for forming the MEMS microphone according to the fourth embodiment, the method includes the following steps:

Step S501, providing a substrate having a first surface and a second surface opposite to each other;

Step S502, forming, on the first surface of the substrate, a sensitive diaphragm and a plurality of interconnects;

Step S503, forming a dielectric layer by which the sensitive diaphragm and the plurality of interconnects are covered, with a plurality of through holes being formed within the dielectric layer, the position of the through hole being corresponding to the sensitive diaphragm and the plurality of interconnects, and the through hole corresponding to the sensitive diaphragm being located in the center of the sensitive diaphragm;

Step S504, filling a low stress conductive material into the through hole, to form a conductive plug and a sensitive diaphragm support which is located on the surface of the sensitive diaphragm, and forming a low stress conductive layer on the surface of the dielectric layer;

Step S505, etching the low stress conductive layer to form, on the surface of the dielectric layer, a sensitive diaphragm support arm, a fixed electrode corresponding to the sensitive diaphragm and a top-layer electrode, with the sensitive diaphragm support arm being coupled to the sensitive diaphragm support, and a plurality of through holes through the fixed electrode being formed within the fixed electrode;

Step S506, forming, within the dielectric layer, a travel stopper corresponding to the edge area of the sensitive diaphragm and used to prevent the sensitive diaphragm from contacting the fixed electrode, and forming a fixed layer partly located on the surface of the travel stopper and partly located on the surface of the dielectric layer;

Step S507, forming an opening within the substrate from the second surface, through which the sensitive diaphragm is exposed; and

Step S508, removing the dielectric layer corresponding to the opening to form a cavity.

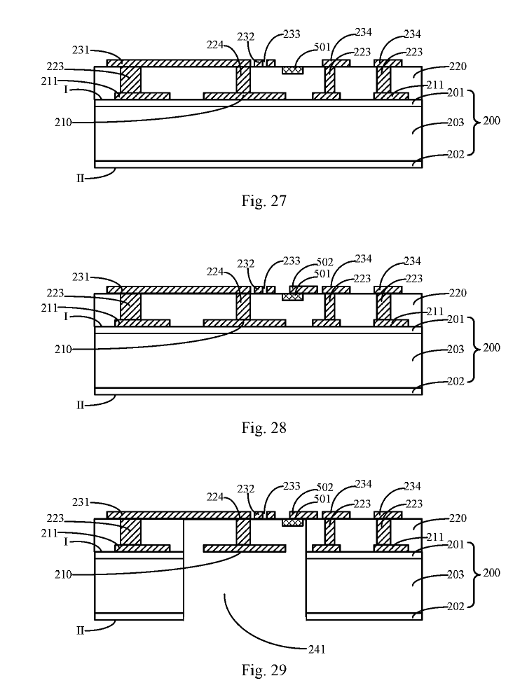

FIG. 27 to FIG. 29 are process diagrams of the method for forming the MEMS microphone according to the fourth embodiment of the present invention.

As for step S501 to step S505, reference may be made to step S201 to step 205 in the first embodiment and FIG. 5 to FIG. 10. A sensitive diaphragm support arm 231, a fixed electrode 232 corresponding to the sensitive diaphragm 210, and a top-layer electrode 234 are formed on the surface of the dielectric layer 220, with the sensitive diaphragm support arm 232 being coupled to the sensitive diaphragm support 224, and a plurality of through holes through the fixed electrode 232 being formed within the fixed electrode 232.

Next, by carrying out step S506, referring to FIG. 27 and FIG. 28, a travel stopper 501 which is corresponding to the edge area of the sensitive diaphragm 210 and used to block the vibrating sensitive diaphragm 210, and a fixed layer 502 partly located on the surface of the travel stopper 501 and partly located on the surface of the dielectric layer 220 are formed within the dielectric layer 220.

Referring to FIG. 27, the travel stopper 501 is made from an insulation material and used to prevent the sensitive diaphragm 210 from contacting the fixed electrode when the sensitive diaphragm 210 vibrates when receiving an acoustic signal. The sensitive diaphragm 210 will not be damaged and the fixed electrode will be protected in the case where the sensitive diaphragm 210 contacts with the travel stopper 501, because the travel stopper 501 is made from a flexible insulation material.

The travel stopper 501 in this embodiment is made from silicon nitride. The travel stopper 501 is located above the edge area of the sensitive diaphragm 210. It is preferable that the travel stopper 501 can prevent the sensitive diaphragm 210 from contacting the fixed electrode but has no influence on the reception of an acoustic signal by the sensitive diaphragm 210. The specific size and position of the travel stopper can be selected by those skilled in the art depending on the actual situation. It should be noted specifically here that the scope of protection of the present invention should not be limited excessively.

A manufacturing process for the travel stopper 501 includes: forming a photoresist pattern (not shown) corresponding to the travel stopper 501 on the dielectric layer 220; etching the dielectric layer 220 by using the photoresist pattern as a mask, so as to form an opening (not shown); and filling silicon nitride into the opening so as to form the travel stopper 501.

It should also be noted that in this embodiment, in order to achieve a better effect the shape of the travel stopper 501 is a plurality of strip-like blocks corresponding to the edge area of the sensitive diaphragm 210. In other embodiments, it has been found by the inventor of the present invention that the travel stopper 501 may also be four strip-like blocks, three strip-like blocks or any other shape. It should be known by those skilled in the art that any travel stopper 501 which can prevent the sensitive diaphragm 210 from contacting the fixed electrode and having no influence on the reception of an acoustic signal by the sensitive diaphragm 210 will fall within the scope of protection of the prevent invention, which will not be listed one by one here.

Referring to FIG. 28, after the travel stopper 501 is formed, a fixed layer 502 partly located on the surface of the travel stopper 501 and partly located on the surface of the dielectric layer 220 is formed by a deposition process.

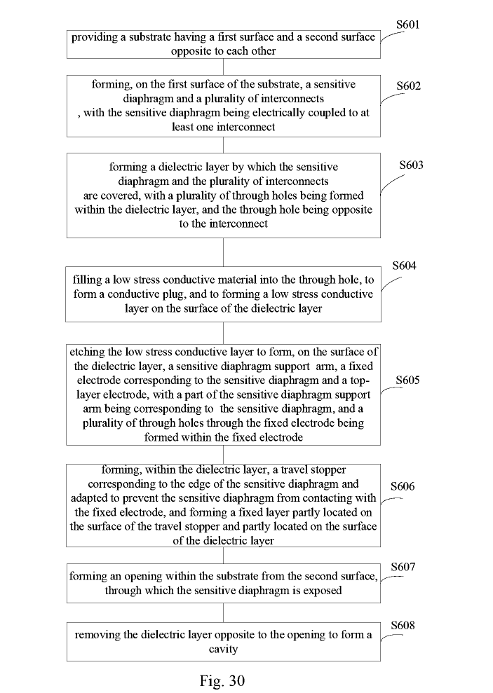

Next, step S507 to step S508 are carried out. Specifically, reference may be made to step S206 to step S207 in the first embodiment, the respective accompanying figures and FIG. 29, which will not be described in detail here.

In the method for forming MEMS microphone according to the fourth embodiment of the present embodiment, the sensitive diaphragm support 224, the conductive plug 223 and the low stress conductive layer 225 are formed at one time by a deposition process. The low stress conductive layer 225 will be etched in the subsequent step so as to form the sensitive diaphragm support arm, the fixed electrode and the top-layer electrode, thereby process steps is simplified and production cost is reduced.

Referring to FIG. 29, the MEMS microphone formed according to the fourth embodiment of the present invention includes: a substrate 200 having a first surface I and a second surface II; an opening 241 through the substrate 200; a plurality of interconnects 211 formed on the first surface of the substrate; a dielectric layer 220 which is formed on the first surface of the substrate and by which the plurality of interconnects 211 are covered; a conductive plug 223 formed within the dielectric layer 220 and electrically coupled to the interconnect 211; a cavity 242 located within the dielectric layer 220 and in communication with the opening; a sensitive diaphragm 210 located within the cavity; a travel stopper 501 corresponding to the edge area of the sensitive diaphragm 210 and used to block the vibrating sensitive diaphragm 210; a sensitive diaphragm support 224 located in the center of the surface of the sensitive diaphragm 210; a sensitive diaphragm support arm 231 partly located on the surface of the dielectric layer 220 and coupled to the sensitive diaphragm support 224; a fixed electrode 232 corresponding to the sensitive diaphragm 210 and surrounded by the travel stopper 301, within which a plurality of through holes 233 through the fixed electrode 232 are formed; a fixed layer 502 partly located on the surface of the travel stopper 501 and partly located the surface of the dielectric layer 220; and a top-layer electrode 234 electrically coupled to the conductive plug 223.

The travel stopper 501 is used to prevent the sensitive diaphragm 210 from contacting the fixed electrode. The sensitive diaphragm 210 will not be damaged and the fixed electrode will be protected as well in the case where the sensitive diaphragm 210 contacts with the travel stopper 501, because the travel stopper 510 is made from a flexible insulation material.

The travel stopper 501 in this embodiment is made from silicon nitride. The travel stopper 501 is located above the edge area of the sensitive diaphragm 210. It is preferable that the travel stopper 501 can prevent the sensitive diaphragm 210 from contacting the fixed electrode but has no influence on the reception of an acoustic signal by the sensitive diaphragm 210. The specific size and position of the travel stopper can be selected by those skilled in the art depending on the actual situation. It should be noted specifically here that the scope of protection of the present invention should not be limited excessively.

The MEMS microphone formed according to the fourth embodiment of the present invention includes the travel stopper 501. The travel stopper 501 is corresponding to the edge area of the sensitive diaphragm 210. The travel stopper 501 can protect the sensitive diaphragm 210 and the fixed electrode 232 during the process of vibration of the sensitive diaphragm 210. Thereby the operating lifetime of the MEMS microphone is increased.

### Fifth Embodiment

An optimized method for forming a MEMS microphone is proposed by the inventor of the present invention. The method for forming the MEMS microphone of the present invention will be described in detail in conjunction with the fifth embodiment below. Referring to FIG. 30, which is a schematic flowchart of the method for forming the MEMS microphone according to the fifth embodiment, the method includes the following steps:

Step S601, providing a substrate having a first surface and a second surface opposite to each other;

Step S602, forming, on the first surface of the substrate, a sensitive diaphragm and a plurality of interconnects, with the sensitive diaphragm being electrically coupled to at least one interconnect;

Step S603, forming a dielectric layer by which the sensitive diaphragm and the plurality of interconnects are covered, with a plurality of through holes being formed within the dielectric layer, and the through hole being corresponding to the interconnect;

Step S604, filling a low stress conductive material into the through hole, to form a conductive plug, and forming a low stress conductive layer on the surface of the dielectric layer;

Step S605, etching the low stress conductive layer to form, on the surface of the dielectric layer, a sensitive diaphragm support arm, a fixed electrode corresponding to the sensitive diaphragm and a top-layer electrode, with the position of a part of the sensitive diaphragm support arm being corresponding to that of the sensitive diaphragm, and a plurality of through holes through the fixed electrode being formed within the fixed electrode;

Step S606, forming, within the dielectric layer, a travel stopper corresponding to the edge area of the sensitive diaphragm and used to prevent the sensitive diaphragm from contacting the fixed electrode, and forming a fixed layer partly located on the surface of the travel stopper and partly located on the surface of the dielectric layer;

Step S607, forming an opening within the substrate from the second surface, through which the sensitive diaphragm is exposed; and

Step S608, removing the dielectric layer corresponding to the opening to form a sensitive diaphragm support located in the center of the sensitive diaphragm and a cavity, with the sensitive diaphragm support being coupled to the sensitive diaphragm support arm.

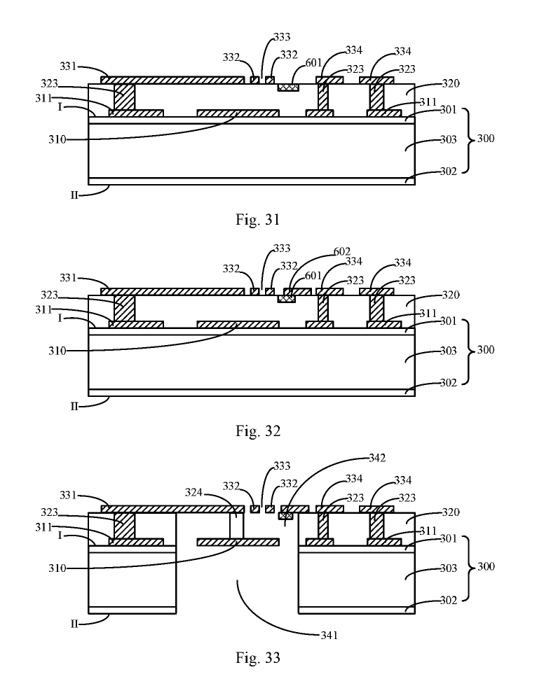

FIG. 31 to FIG. 33 are process diagrams of the method for forming the MEMS microphone according to the fifth embodiment of the present invention;

As for step S601 to step S605, reference may be made to step S301 to step 305 in the second embodiment and FIG. 15 to FIG. 21. A sensitive diaphragm support arm 331, a fixed electrode 332 corresponding to the sensitive diaphragm 310, and a top-layer electrode 334 are formed on the surface of the dielectric layer 320. Specifically, the position of a part of the sensitive diaphragm support arm 331 is corresponding to that of the sensitive diaphragm 310, and a plurality of through holes 333 through the fixed electrode 332 are formed within the fixed electrode 332.

Next, by carrying out step S606, referring to FIG. 31, a travel stopper corresponding to the edge area of the sensitive diaphragm 310 and used to block the vibrating sensitive diaphragm 310 is formed within the dielectric layer 320.

The travel stopper 601 is used to prevent the sensitive diaphragm 310 from contacting the fixed electrode. Due to the presence of the travel stopper 601, the sensitive diaphragm 310 will not be damaged and the fixed electrode will be protected as well in the case where the sensitive diaphragm 310 contacts with the travel stopper 601.

The travel stopper 601 in this embodiment is made from silicon nitride. The travel stopper 601 is located above the edge area of the sensitive diaphragm 310. It is preferable that the travel stopper 601 can prevent the sensitive diaphragm 310 from contacting the fixed electrode but has no influence on the reception of an acoustic signal by the sensitive diaphragm 310. The specific size and position of the travel stopper can be selected by those skilled in the art depending on the actual situation. It should be noted specifically here that the scope of protection of the present invention should not be limited excessively.

A manufacturing process for the travel stopper 601 includes: forming a photoresist pattern (not shown) corresponding to the travel stopper 601 on the dielectric layer 320; etching the dielectric layer by using the photoresist pattern as a mask, so as to form an opening (not shown); and filling silicon nitride into the opening so as to form the travel stopper 601.

Referring to FIG. 32, a fixed layer 602 partly located on the surface of the travel stopper 601 and partly located on the surface of the dielectric layer 220 is formed by a deposition process and etching process after the travel stopper 601 is formed.

It should also be noted that in this embodiment, the shape of the travel stopper 601 is a plurality of strip-like blocks corresponding to the edge area of the sensitive diaphragm 310, in order to achieve a better effect. In other embodiments, it has been found by the inventor of the present invention that the travel stopper 601 may also be four strip-like blocks, three strip-like blocks or any other shape. It should be known by those skilled in the art that any travel stopper 601 which can prevent the sensitive diaphragm 210 from contacting the fixed electrode and having no influence on the reception of an acoustic signal by the sensitive diaphragm 310 will fall within the scope of protection of the prevent invention, which will not be listed one by one here.

Next, step S607 to step S608 are carried out. Accordingly, reference may be made to step S306 to step S307 in the second embodiment, the respective accompanying figures and FIG. 33, which will not be described in detail here.

It should be noted that in the method for forming MEMS microphone according to the fifth embodiment of the present embodiment, the sensitive diaphragm support 324 located in the position of the surface of the sensitive diaphragm 310 is formed while a cavity is formed by etching the dielectric layer 320, and no additional process step is needed to form the sensitive diaphragm support 324, thereby process steps are simplified and production cost is reduced. In the method for forming MEMS microphone according to the fifth embodiment of the present embodiment, the travel stopper 601 is formed. The travel stopper 601 can prevent the sensitive diaphragm 310 from contacting the fixed electrode. The sensitive diaphragm 310 will not be damaged and the fixed electrode will be protected as well in the case where the sensitive diaphragm 310 contacts with the travel stopper 601, because the travel stopper 601 is made from a flexible insulation material.

Referring to FIG. 33, the MEMS microphone formed according to the fifth embodiment of the present invention includes: a substrate 300 having a first surface I and a second surface II; an opening 341 through the substrate 300; a plurality of interconnects 311 formed on the first surface of the substrate; a dielectric layer 320 which is formed on the first surface of the substrate and by which the plurality of interconnects 311 are covered; a conductive plug 223 formed within the dielectric layer 320 and electrically coupled to the interconnect 311; a cavity 342 located within the dielectric layer 320 and in communication with the opening; a sensitive diaphragm 310 located within the cavity; a travel stopper 601 corresponding to the edge area of the sensitive diaphragm 310 and used to block the vibrating sensitive diaphragm 310; a sensitive diaphragm support 324 located in the center of the surface of the sensitive diaphragm 310; a sensitive diaphragm support arm 331 partly located on the surface of the dielectric layer 320 and coupled to the sensitive diaphragm support 324; a fixed electrode 332 corresponding to the sensitive diaphragm 310, within which a plurality of through holes 333 through the fixed electrode 332 are formed; a fixed layer 602 partly located on the surface of the travel stopper 601 and partly located on the surface of the dielectric layer 320; and a top-layer electrode 334 electrically coupled to the conductive plug 323.

### Sixth Embodiment

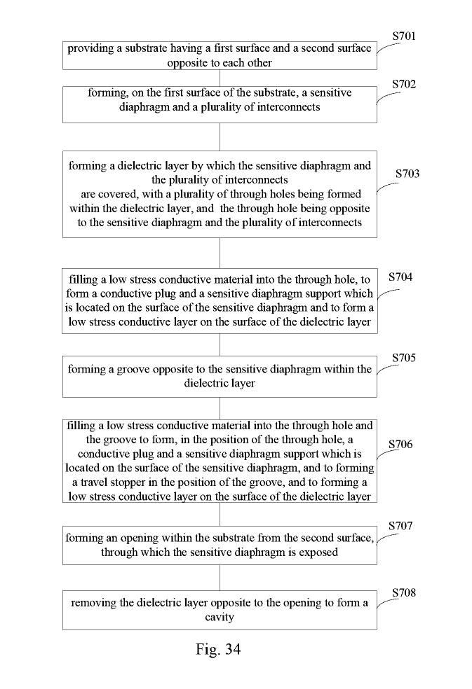

An optimized method for forming a MEMS microphone is proposed by the inventor of the present invention. The method for forming the MEMS microphone of the present invention will be described in detail in conjunction with the sixth embodiment below. Referring to FIG. 34, which is a schematic flowchart of the method for forming the MEMS microphone according to the sixth embodiment, the method includes the following steps:

Step S701, providing a substrate having a first surface and a second surface opposite to each other;

Step S702, forming, on the first surface of the substrate, a sensitive diaphragm and a plurality of interconnects;

Step S703, forming a dielectric layer by which the sensitive diaphragm and the plurality of interconnects are covered, with a plurality of through holes being formed within the dielectric layer, and the position of the through hole being corresponding to that of the sensitive diaphragm and the plurality of interconnects;

Step S704, forming a groove corresponding to the sensitive diaphragm within the dielectric layer;

Step S705, filling a low stress conductive material into the through hole and the groove to form, in the position of the through hole, a conductive plug and a sensitive diaphragm support which is located on the surface of the sensitive diaphragm, forming a travel stopper in the position of the groove, and forming a low stress conductive layer on the surface of the dielectric layer;

Step S706, etching the low stress conductive layer to form, on the surface of the dielectric layer, a sensitive diaphragm support arm, a fixed electrode corresponding to the sensitive diaphragm and a top-layer electrode, with the sensitive diaphragm support arm being coupled to the sensitive diaphragm support, and a plurality of through holes through the fixed electrode being formed within the fixed electrode;

Step S707, forming an opening within the substrate from the second surface, through which the sensitive diaphragm is exposed; and

Step S708, removing the dielectric layer corresponding to the opening to form a cavity.

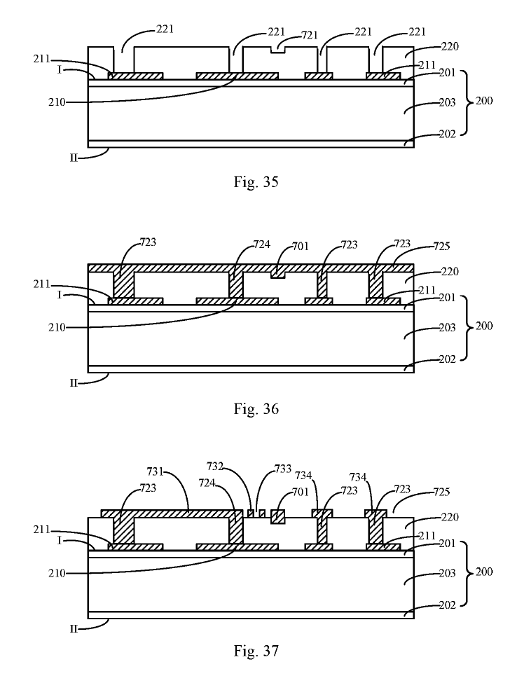

FIG. 35 to FIG. 37 are process diagrams of the method for forming the MEMS microphone according to the sixth embodiment of the present invention.

As for step S701 to step S703, reference may be made to step S201 to step 203 in the first embodiment and FIG. 5 to FIG. 8. The dielectric layer 220 is formed, by which the sensitive diaphragm 210 and the plurality of interconnects 211 are covered, with a plurality of through holes 221 being formed within the dielectric layer 220, the position of the through hole 221 being corresponding to that of the sensitive diaphragm 210 and the plurality of interconnects 211, and the through hole 221 which has a position corresponding to the position of the sensitive diaphragm 210 being located in the center of the sensitive diaphragm 210.

Referring to FIG. 35, by carrying out step S704, a groove 721 corresponding to the sensitive diaphragm 210 is formed within the dielectric layer 220.

A manufacturing process for the groove 721 is etching process. The specific manufacturing process includes: forming a photoresist pattern on the surface of the dielectric layer 220, which is corresponding to the groove 721; and etching the dielectric layer 220 by using the photoresist pattern as a mask, so as to form the groove 721.

The groove 721 is adapted to be filled with polycrystalline silicon to form a travel stopper in the subsequent step.

It should be noted that the depth of the groove 721 is smaller than the thickness of the dielectric layer 220. Preferably, the depth of the groove 721 should be such that the travel stopper to be formed later can prevent the sensitive diaphragm 210 from contacting the fixed electrode. The depth of the groove 721 can be selected by those skilled in the art depending on the actual parameters of the MEMS microphone. It should be noted specifically here that the scope of protection of the present invention should not be limited excessively.

Referring to FIG. 36, by carrying out step S705, a low stress conductive material is filled into the through hole 221 and the groove 721 so as to form, in the position of the through hole 221, a conductive plug 723 and a sensitive diaphragm support 724 located on the surface of the sensitive diaphragm 210, and to form a travel stopper 701 in the position of the groove 721, and to form a low stress conductive layer 725 on the surface of the dielectric layer 220.

The filling of the low stress conductive material and the forming of the low stress conductive layer 225 are carried out in the same deposition process, such as a low pressure chemical vapor deposition, a plasma-assisted enhanced vapor deposition process or an atomic layer stack deposition. The deposition process can be selected by those skilled in the art depending on a specific size of the through hole 221 and the groove 721, which will not be described in detail here.

In this step, the sensitive diaphragm support 724, the conductive plug 723, the travel stopper 701 and the low stress conductive layer 725 are formed at one time by a deposition process. The low stress conductive layer 725 will be etched in the subsequent step so as to form a sensitive diaphragm support arm, a fixed electrode and a top-layer electrode, thereby process steps are simplified and production cost is reduced.

In this embodiment, the material of the sensitive diaphragm support 724 is the same as that of the sensitive diaphragm support arm, the fixed electrode and the top-layer electrode, which is a low stress conductive material, such as low stress polycrystalline silicon.

In this embodiment, the sensitive diaphragm support 724 is located on the surface of the sensitive diaphragm 210, so that the interference on the vibration of the sensitive diaphragm 210 can be reduced when the sensitive diaphragm 210 is sensing an acoustic signal to vibrate, thereby the sensitivity of the MEMS microphone of the present invention will be improved.

The travel stopper 701 is used to prevent the sensitive diaphragm 210 from contacting the fixed electrode when the sensitive diaphragm 210 vibrates when receiving an acoustic signal. Due to the presence of the travel stopper 701, the sensitive diaphragm 210 will not be damaged and the fixed electrode will be protected as well in the case where the sensitive diaphragm 210 contacts with the travel stopper 701.

Referring FIG. 37, by carrying out step S706, the low stress conductive layer 725 is etched to form, on the surface of the dielectric layer 220, a sensitive diaphragm support arm 731, a fixed electrode 732 corresponding to the sensitive diaphragm 210 and a top-layer electrode 734, with the sensitive diaphragm support arm 731 being coupled to the sensitive diaphragm support 724, and a plurality of through holes 733 through the fixed electrode 732 being formed within the fixed electrode 732.

The fixed electrode 732 is adapted to form a capacitor with the sensitive diaphragm 210 formed previously, and the acoustic signal sensed by the capacitor is converted into an electrical signal.

The through hole 733 through the fixed electrode 732 is formed in the fixed electrodes 732. The through hole 733 is adapted to transmit an acoustic signal, so that the acoustic signal is able to pass through the fixed electrode 732 without being isolated, therefore the acoustic signal can be sensed by the sensitive diaphragm 210.

In this embodiment, the sensitive diaphragm support 724 is located on the surface of the sensitive diaphragm 210, so that the interference on the vibration of sensitive diaphragm 210 can be reduced when the sensitive diaphragm 210 is sensing an acoustic signal to vibrate, thereby the sensitivity of the MEMS microphone of the present invention will be improved.

As for step S707 and step S708, reference may be made to step S206 and step S207 in the first embodiment and the respective accompanying figures, which will not be described in detail here.

In the method for forming MEMS microphone according to the sixth embodiment of the present embodiment, the travel stopper 701 adapted to prevent the sensitive diaphragm 210 from contacting the fixed electrode is formed, moreover the travel stopper 701 is formed by means of the deposition process for forming the sensitive diaphragm support 724, the conductive plug 723 and the low stress conductive layer 725, and no addition deposition process is necessary, thereby process steps are simplified and production cost is reduced.

### Seventh Embodiment

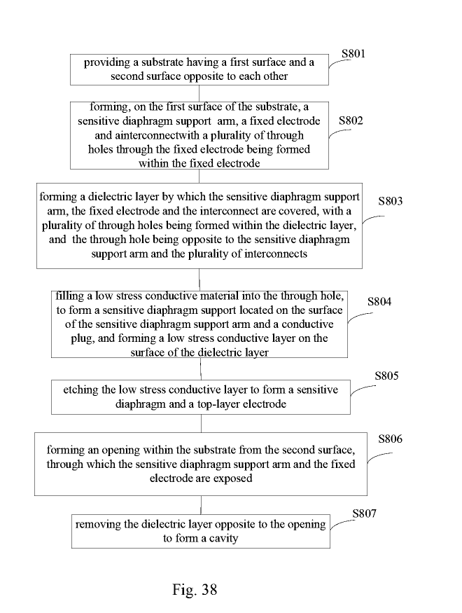

An optimized method for forming a MEMS microphone is proposed by the inventor of the present invention. The method for forming the MEMS microphone of the present invention will be described in detail in conjunction with the seventh embodiment below. Referring to FIG. 38, which is a schematic flowchart of the method for forming the MEMS microphone according to the seventh embodiment, the method includes the following steps:

Step S801, providing a substrate having a first surface and a second surface opposite to each other;

Step S802, forming, on the first surface of the substrate, a sensitive diaphragm support arm, a fixed electrode and a interconnect, with a plurality of through holes through the fixed electrode being formed within the fixed electrode;

Step S803, forming a dielectric layer by which the sensitive diaphragm support arm, the fixed electrode and the interconnect are covered, with a plurality of through holes being formed within the dielectric layer, and the position of the through hole being corresponding to that of the sensitive diaphragm and the plurality of interconnects;

Step S804, filling a low stress conductive material into the through hole, to form a sensitive diaphragm support located on the surface of the sensitive diaphragm and a conductive plug, and forming a low stress conductive layer on the surface of the dielectric layer;

Step S805, etching the low stress conductive layer to form a sensitive diaphragm and a top-layer electrode;

Step S806, forming an opening within the substrate from the second surface, through which the sensitive diaphragm support arm and the fixed electrode are exposed; and

Step S807, removing the dielectric layer corresponding to the opening to form a cavity.

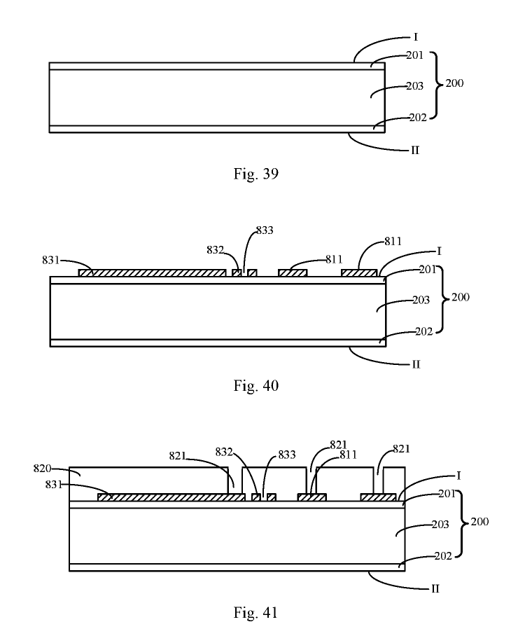

FIG. 39 to FIG. 45 are process schematic diagrams of the method for forming the MEMS microphone according to the seventh embodiment of the present invention.

Referring to FIG. 39, by carrying out step S801, a substrate 200 is provided, and the substrate has a first surface I and a second surface II opposite to each other.

The substrate 200 may be made from a semiconductor material, for example, the substrate 200 may be made from single crystal semiconductor material such as single crystal silicon, single crystal germanium-silicon, or single crystal GaAs, single crystal GaN (e.g., a group II-VI compound semiconductor and a group III-V compound semiconductor). The substrate 200 may also be a polycrystalline substrate or an amorphous substrate, for example, the substrate may be made from polycrystalline silicon or other materials. The material of the substrate 200 can be selected by those skilled in the art depending on the MEMS microphone to be formed. It should be noted specifically here that the scope of protection of the present invention should not be limited excessively.

It should also be noted that, in order to improve the performance of the MEMS microphone to be formed, the substrate 200 may also have a single layer structure or a multilayer stack structure, or the substrate 200 may also be a substrate in which a semiconductor device or other circuit such as a drive circuit and/or a signal processing circuit is formed. As one example of the present invention, the substrate 200 is a single crystal silicon substrate 203 having an upper surface on which an isolation layer 201 is formed and a lower surface on which an insulating layer 202 is formed. The first surface I of the substrate 200 is the upper surface of the isolation layer 201, and the second surface II of the substrate 200 is the lower surface of the insulating layer 202. The isolation layer 201 is adapted to isolate a sensitive diaphragm and a plurality of interconnects formed in the subsequent step, and the insulating layer 202 is adapted to prevent the substrate 200 from being damaged in the subsequent process.

The material of the isolation layer 201 and the insulating layer 202 may be silicon oxide, silicon nitride or silicon oxynitride. It should also be noted that, in order to improve the performance of the MEMS microphone to be formed, the isolation layer 201 and the insulating layer 202 may be a single layer structure or a multilayer stack structure. For example, the isolation layer 201 is a stack structure of silicon oxide and silicon nitride, and the insulating layer 202 is a stack structure of silicon oxide and silicon nitride. The process for forming the isolation layer 201 and the insulating layer 202 is a deposition process or a thermal oxidation process. In this embodiment, the material of the isolation layer 201 and the insulating layer 202 may be silicon oxide, and are formed by performing oxidation on the upper surface and the lower surface of the single crystal silicon substrate 203 by a thermal oxidation process. The thickness and the material of the isolation layer 201 and the insulating layer 202 may be selected by those skilled in the art depending on the MEMS microphone to be formed. It should be noted specifically here that the scope of protection of the present invention should not be limited excessively.

Referring to FIG. 40, by carrying out step S802, a sensitive diaphragm support arm 831, a fixed electrode 832 and a interconnect 811 are formed on the first surface I of the substrate 200, with a plurality of through holes 833 through the fixed electrode 832 being formed within the fixed electrode 832.

The sensitive diaphragm support arm 831 is adapted to constitute a cantilever structure with the sensitive diaphragm support to be formed later, so that the stress on the sensitive diaphragm to be formed later is low.

The fixed electrode 832 is adapted to constitute a capacitor structure with a sensitive diaphragm to be formed later. And the electrical signal converted from an acoustic signal is transmitted to other assemblies, such as a interconnect 811.

The through hole 833 through the fixed electrode 832 is formed in the fixed electrodes 832. The through hole 833 is adapted to transmit an acoustic signal, so that the acoustic signal is able to pass through the fixed electrode 832 without being isolated, therefore the acoustic signal can be sensed by the sensitive diaphragm.

The interconnect 811 is adapted to transmit an electrical signal of the MEMS microphone. The interconnect 811 is made from a conductive material. The position where the interconnect 811 is formed, the number and the shape of the interconnect 811 may be determined depending on the specific MEMS microphone. It should be noted that the interconnect 811 may specifically be a solder pad or a wire. The required interconnect can be selected by those skilled in the art depending on the MEMS microphone to be formed. It should be noted specifically here that the scope of protection of the present invention should not be limited excessively.

The forming step of the sensitive diaphragm support arm 831, the fixed electrode 832 and the interconnect 811 includes:

forming a polycrystalline silicon layer (not shown) on the first surface I of the substrate 200, wherein the specific process for forming the polycrystalline silicon layer may be a deposition process, such as chemical vapor deposition;

forming a photoresist layer (not shown) on the surface of the polycrystalline silicon layer, wherein the manufacturing process for the photoresist layer is a spin coating process, and as for the specific step, reference may be made to the existing forming step of the polycrystalline silicon layer, which will not be described in detail here;

exposing and developing the photoresist layer using a mask corresponding to the sensitive diaphragm support arm 831, the fixed electrode 832, the interconnect 811 and the through hole 833 so as to form a photoresist pattern; and

etching the polycrystalline silicon thin film by using the photoresist pattern as a mask, until the first surface I of the substrate 200 is exposed, so as to form the sensitive diaphragm support arm 831, the fixed electrode 832 and the interconnect 811, wherein the etching process may be a dry etching or a wet etching, and a plurality of through holes 833 through the fixed electrode 832 are formed within the fixed electrode 832.

Referring to FIG. 41, by carrying out step S803, a dielectric layer 820 is formed, by which the sensitive diaphragm support arm 831, the fixed electrode 832 and the interconnect 811 are covered, with a plurality of through holes 821 being formed within the dielectric layer 820, and the position of the through hole 821 being corresponding to that of the sensitive diaphragm support arm 831 and the plurality of interconnects 811.

The dielectric layer 820 is made from a material which has a selective etching characteristic with respect to a sensitive diaphragm to be formed later and the interconnect 820. Specifically, the dielectric layer 820 is made from silicon oxide.

The dielectric layer 820 is adapted to provide a work platform for a cavity of the MEMS microphone to be formed later, and electrically isolate the interconnect 811 from a conductive electrode to be formed later.

The manufacturing process for the dielectric layer 820 is a deposition process, and is preferably a chemical vapor deposition process.

The manufacturing process for the through hole 821 is an etching process, and the specific manufacturing process includes: forming a photoresist pattern corresponding to the through hole 821 on the surface of the dielectric layer 820; and etching the dielectric layer 820 by using the photoresist pattern as a mask, so as to form the through hole 821.

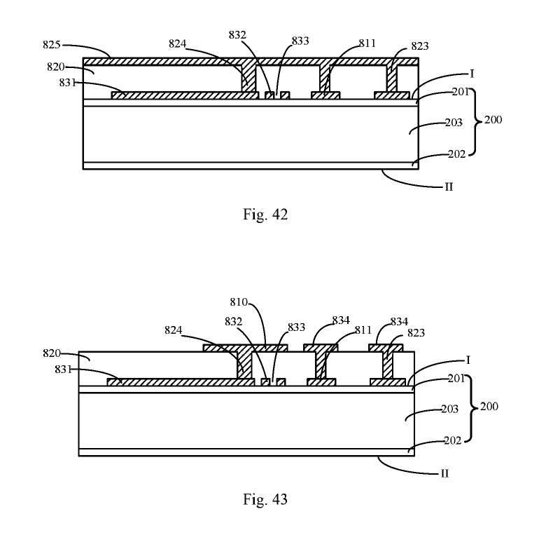

Step S804 is carried out, referring to FIG. 42, in which a low stress conductive material is filled into the through hole to form a sensitive diaphragm support 824 located on the surface of the sensitive diaphragm support and a conductive plug 823, and to form a low stress conductive layer 825 on the surface of the dielectric layer 820.

It should be noted that in this step, the sensitive diaphragm support, the conductive plug and the low stress conductive layer are formed at one time by a deposition process. The low stress conductive layer will be etched in the subsequent step so as to form a sensitive diaphragm and a top-layer electrode. Thereby process steps are simplified and production cost is reduced.

In this embodiment, the material of the sensitive diaphragm support 824 is the same as that of a sensitive diaphragm and a top-layer electrode, which is a low stress conductive material, such as a polycrystalline silicon material.

The filling of the low stress conductive material and the forming of the low stress conductive layer are carried out in the same deposition process, such as a low pressure chemical vapor deposition, a plasma-assisted enhanced vapor deposition process or an atomic layer stack deposition. The deposition process can be selected by those skilled in the art depending on a specific size of the through hole 221, which will not be described in detail here.

Referring to FIG. 43, by carrying out step S805, the low stress conductive layer is etched to form a sensitive diaphragm 810 and a top-layer electrode 834.

The sensitive diaphragm 810 is adapted to form a capacitor with the fixed electrode. The sensitive diaphragm 810 may vibrate under the influence of an acoustic signal, and the acoustic signal will be converted into an electrical signal. The material of the sensitive diaphragm 810 is low stress polycrystalline silicon, and the sensitive diaphragm 810 may be square, circular or other shapes. A suitable shape of the sensitive diaphragm 810 may be selected by those skilled in the art depending on the MEMS microphone to be formed. It should be noted specifically here that the scope of protection of the present invention should not be limited excessively. It should also be noted specifically here that since the sensitive diaphragm 810 is made from low stress polycrystalline silicon, the size and the production cost of the MEMS microphone adopting the sensitive diaphragm 810 can be further reduced.

Furthermore, the sensitive diaphragm support 824 is located in the center of the sensitive diaphragm 810, so that the interference of the sensitive diaphragm support 824 on the vibration of the sensitive diaphragm can be reduced when the sensitive diaphragm 810 is sensing an acoustic signal to vibrate, thereby the sensitivity of the MEMS microphone of the present invention will be improved.

In this embodiment, the top-layer electrode 834 may serve as supporting platform of the bonding pad. The distribution and the shape of the top-layer electrode 834 can be selected by those skilled in the art depending on a specific design of the MEMS microphone. It should be noted specifically here that the scope of protection of the present invention should not be limited excessively.

It should also be noted that in this embodiment, the top-layer electrode 834 is formed in the same deposition process and the same etching process as the sensitive diaphragm 810. In other embodiments, a metal layer may also be deposited by an additional metal deposition process, and the metal layer is etched to form the top-layer electrode. It should be noted specifically here the top-layer electrode of the metal may serve as a bonding pad directly, and no additional process and step of forming the bonding pad is needed.

The specific forming step of the sensitive diaphragm 810 and the top-layer electrode 834 includes: forming a photoresist pattern on the surface of the low stress conductive layer 825, with the photoresist pattern being corresponding to the sensitive diaphragm 810 and a top-layer electrode 834; and etching the low stress conductive layer 825 by using the photoresist pattern as a mask, so as to form the sensitive diaphragm 810 and the top-layer electrode 834.

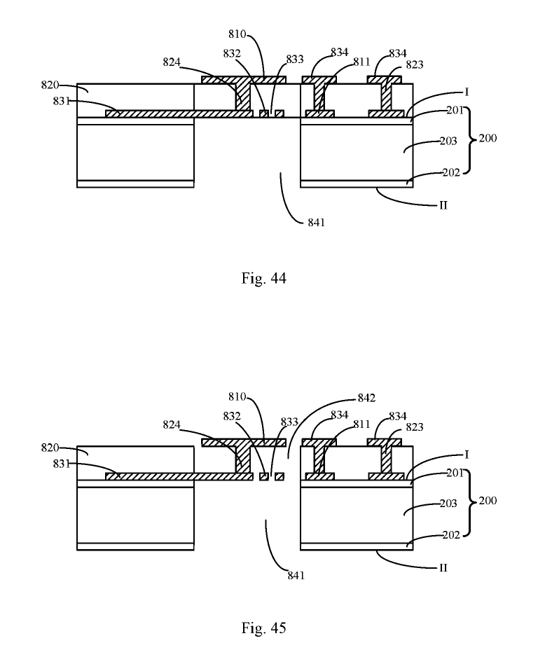

Referring to FIG. 44, by carrying out step S806, an opening 841 is formed within the substrate from the second surface, through which the fixed electrode 832 and a part of the sensitive diaphragm support arm 831 are exposed.

The manufacturing process for the opening 841 is an etching process, and specifically, may be a wet etching or a dry etching.

Specifically, the manufacturing process for the opening 841 includes: forming, on the second surface II, a photoresist pattern corresponding to the opening 841; and etching the substrate 200 by using the photoresist pattern as a mask, until part of the sensitive diaphragm support arm 831 and the fixed electrode 832 are exposed, so as to form the opening 841.

The opening 841 is adapted to constitute a part of a cavity, thus the sensitive diaphragm 810 is released, so that the sensitive diaphragm 810 is able to vibrate within the cavity when an acoustic signal is sensed by the sensitive diaphragm 810, and the acoustic signal is converted into an electrical signal.

Referring to FIG. 45, by carrying out step S807, the dielectric layer 820 corresponding to the opening 841 is removed to form a cavity 842.

The material of the dielectric layer 820 is a material which has a selective etching characteristic with respect to the sensitive diaphragm 810 and the interconnect 811. In this step, the dielectric layer 820 corresponding to the opening 841 can be removed without damaging the sensitive diaphragm 810, the interconnect 811 and the sensitive diaphragm support 824, as long as the etching process has a high etching selectivity ratio with respect to the dielectric layer 820.

The etching process may be a dry etching or a wet etching.

It should also be noted that when removing the dielectric layer 820 corresponding to the opening 841, the dielectric layer 820 may be removed from two sides of the opening 841 and the though hole 833, so that the dielectric layer 820 will be removed faster.

The method for forming the MEMS microphone in this embodiment has a simple process, and the sensitive diaphragm 810 is formed in the same deposition process as the sensitive diaphragm support 824, thereby process steps are simplified and production cost is reduced.

Referring to FIG. 45, the MEMS microphone formed according to the seventh embodiment of the method for forming the MEMS microphone includes:

a substrate 200 having a first surface I and a second surface II; an opening 841 through the substrate 200; a plurality of interconnects 811 formed on the first surface of the substrate; a dielectric layer 820 which is formed on the first surface of the substrate and by which the plurality of interconnects 811 are covered; a conductive plug 823 formed within the dielectric layer 820 and electrically coupled to the interconnect 811; a cavity 842 located within the dielectric layer 820 and in communication with the opening; a sensitive diaphragm 810 located within the cavity; a sensitive diaphragm support 824 located on the surface of the sensitive diaphragm 810; a sensitive diaphragm support arm 831 partly located on the first surface I of the substrate 200 and coupled to the sensitive diaphragm support 824; a fixed electrode 832 corresponding to the sensitive diaphragm 810, within which a plurality of through holes 833 through the fixed electrode 832 are formed; and a top-layer electrode 834 electrically coupled to a conductive plug 823.

The material of a sensitive diaphragm support 824 is consistent with that of the sensitive diaphragm 810, which is low stress polycrystalline silicon.

It should be noted that the sensitive diaphragm 810 of the MEMS microphone formed in this embodiment is located on the surface of the cavity 842. However, since the MEMS microphone formed in this embodiment is an intermediate product, a big cavity may be formed in the subsequent encapsulation on the basis of the cavity 842. By the big cavity, it allows forming a variable capacitor by the sensitive diaphragm with the fixed electrode. Under the action of an acoustic signal, the capacitance of the variable capacitor changes. The dimension, shape and size of the cavity can be selected by those skilled in the art depending on the actual need. It should be noted specifically here that the scope of protection of the present invention should not be limited excessively.

In the MEMS microphone formed in this embodiment, the influence of the external stress on the sensitive diaphragm is low, and thereby the sensitivity of the MEMS microphone will be improved. The size and the production cost of the MEMS microphone of the present invention can be further reduced, because there is no stress influence on the MEMS microphone.

Furthermore, the MEMS microphone formed in this embodiment has a structure in which a sensitive diaphragm support 824 is located in the center of the surface of the sensitive diaphragm 810, so that the influence of the external stress on the sensitive diaphragm can be further reduced.

It should also be noted that at least one sensitive diaphragm support 824 is provided, while the number of the sensitive diaphragm support 824 in other embodiments may be 2, 3 or more. The center of a pattern formed by a plurality of sensitive diaphragm supports 824 coincides with the center of the surface of the sensitive diaphragm 810, in the case where a plurality of sensitive diaphragm supports 824 are provided.

### Eighth Embodiment

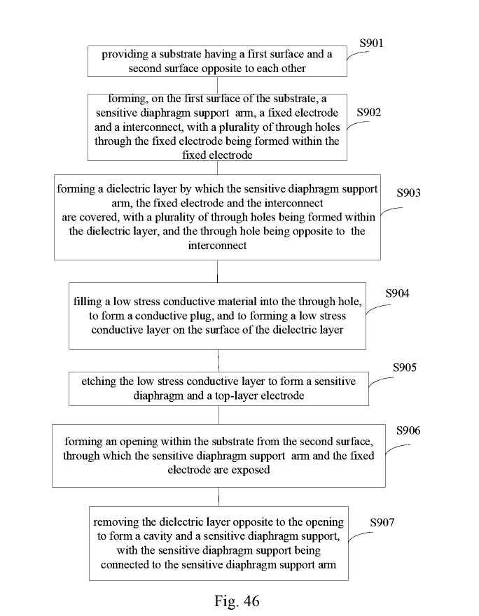

An optimized method for forming a MEMS microphone is proposed by the inventor of the present invention. The method for forming the MEMS microphone of the present invention will be described in detail in conjunction with the eighth embodiment below. Referring to FIG. 46, which is a schematic flowchart of the method for forming the MEMS microphone according to the eighth embodiment, the method includes the following steps:

Step S901, providing a substrate having a first surface and a second surface opposite to each other;

Step S902, forming, on the first surface of the substrate, a sensitive diaphragm support arm, a fixed electrode and an interconnect, with a plurality of through holes through the fixed electrode being formed within the fixed electrode;

Step S903, forming a dielectric layer by which the sensitive diaphragm support arm, the fixed electrode and the interconnect are covered, with a plurality of through holes being formed within the dielectric layer, and the position of the through hole being corresponding to that of the interconnect;

Step S904, filling a low stress conductive material into the through hole, to form a conductive plug, and forming a low stress conductive layer on the surface of the dielectric layer;

Step S905, etching the low stress conductive layer to form a sensitive diaphragm and a top-layer electrode;

Step S906, forming an opening within the substrate from the second surface, through which the sensitive diaphragm support arm and the fixed electrode are exposed; and

Step S907, removing the dielectric layer corresponding to the opening to form a cavity and a sensitive diaphragm support, with the sensitive diaphragm support being coupled to the sensitive diaphragm support arm.

As for the detailed description of the method for forming the MEMS microphone according to the eighth embodiment, reference is made to the forming method in the second and the seventh embodiment, which will not be described in detail here.

In the method for forming the MEMS microphone according to this embodiment, the sensitive diaphragm support is formed in the step of removing the dielectric layer. The method for forming the MEMS microphone according to this embodiment has a simple process, and the production cost is low.

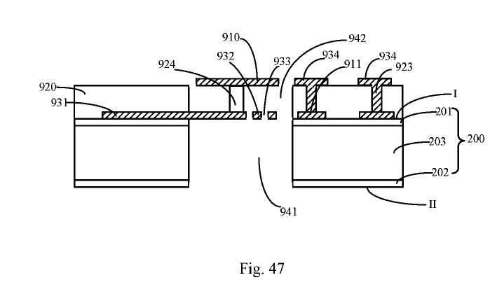

Referring to FIG. 47, the MEMS microphone which is formed by the forming method described above includes: a substrate 200 having a first surface I and a second surface II; an opening 941 through the substrate 200; a plurality of interconnects 911 formed on the first surface of the substrate; a dielectric layer 920 which is formed on the first surface of the substrate and by which the plurality of interconnects 911 are covered; a conductive plug 923 formed within the dielectric layer 920 and electrically coupled to the interconnect 911; a cavity 942 located within the dielectric layer 920 and in communication with the opening; a sensitive diaphragm 910 located within the cavity; a sensitive diaphragm support 924 located on the surface of the sensitive diaphragm 910; a sensitive diaphragm support arm 931 partly located on the first surface I of the substrate 200 and to the sensitive diaphragm support 924; a fixed electrode 932 corresponding to the sensitive diaphragm 910, within which a plurality of through holes 933 through the fixed electrode 932 are formed; and a top-layer electrode 934 electrically coupled to a conductive plug 923.

The material of a sensitive diaphragm support 924 is consistent with that of the sensitive diaphragm 910. The material of the sensitive diaphragm support 924 is silicon oxide.

In the MEMS microphone formed in this embodiment, the influence of the external on the stress the sensitive diaphragm is low, and thereby the sensitivity of the MEMS microphone will be improved. The size and the production cost of the MEMS microphone of the present invention can be further reduced because there is no stress influence on the MEMS microphone.

Furthermore, the MEMS microphone formed in this embodiment has a structure in which the sensitive diaphragm support 924 is located in the center of the surface of the sensitive diaphragm 910, so that the influence of the environment on the sensitive diaphragm can be further reduced.

It should also be noted that at least one sensitive diaphragm support 924 is provided, while the number of the sensitive diaphragm support 924 in other embodiments may be 2, 3 or more. The center of a pattern formed by a plurality of sensitive diaphragm supports 924 coincides with the center of the surface of the sensitive diaphragm 910, in the case where a plurality of sensitive diaphragm supports 924 are provided.

### Ninth Embodiment

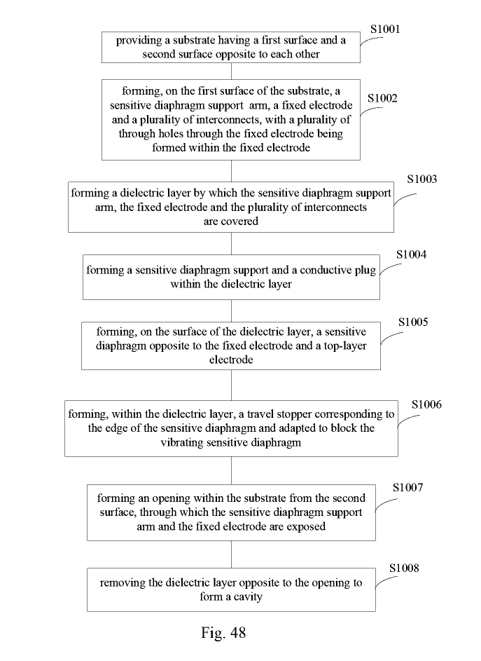

An optimized method for forming a MEMS microphone is proposed by the inventor of the present invention. The method for forming the MEMS microphone of the present invention will be described in detail in conjunction with the ninth embodiment below. Referring to FIG. 48, which is a schematic flowchart of the method for forming the MEMS microphone according to the ninth embodiment, the method includes the following steps:

Step S1001, providing a substrate having a first surface and a second surface opposite to each other;

Step S1002, forming, on the first surface of the substrate, a sensitive diaphragm support arm, a fixed electrode and a plurality of interconnects, with a plurality of through holes through the fixed electrode being formed within the fixed electrode;

Step S1003, forming a dielectric layer by which the sensitive diaphragm support arm, the fixed electrode and the plurality of interconnects are covered;

Step S 1004, forming a sensitive diaphragm support and a conductive plug within the dielectric layer;

Step S1005, forming, on the surface of the dielectric layer, a sensitive diaphragm corresponding to the fixed electrode and a top-layer electrode;

Step S1006, forming, within the dielectric layer, a travel stopper corresponding to the edge area of the sensitive diaphragm and used to block the vibrating sensitive diaphragm;

Step S1007, forming an opening within the substrate from the second surface, through which the sensitive diaphragm support arm and the fixed electrode are exposed; and

Step S1008, removing the dielectric layer corresponding to the opening to form a cavity.

As for the detailed description of the method for forming the MEMS microphone according to the ninth embodiment, reference is made to the forming method in the fifth and the seventh embodiment, which will not be described in detail here.

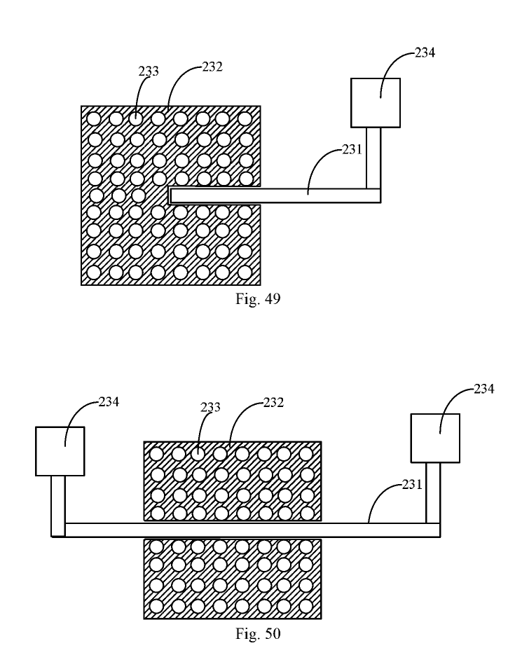

It should also be noted that the sensitive diaphragm support arm of the MEMS microphone according to another embodiment may be a single pedal or crossing-over the fixed electrode 232. Referring to FIG. 49, which is a schematic diagram of the MEMS microphone according to another embodiment of the present invention, it is an embodiment in which the sensitive diaphragm support arm is a single pedal.

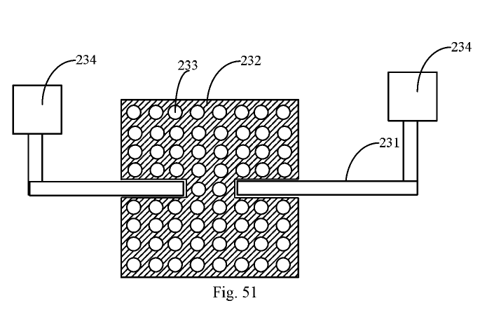

As for the MEMS microphone according to yet another embodiment of the present invention, reference is made to FIG. 50. It is an embodiment in which the sensitive diaphragm support arm is crossing-over the fixed electrode 232.

A single pedal or crossing-over the fixed electrode 232 may be selected flexibility as the sensitive diaphragm support arm 231 according to the present invention without causing an additional problem of stress on MEMS microphone. The MEMS microphone of the present invention has a stable structure and a high selectivity of design.

Reference is made to FIG. 51, which is a schematic diagram according to still another embodiment of the present invention. In this embodiment, the MEMS microphone has two sensitive diaphragm supports, and the centers of the two sensitive diaphragm supports coincide with the center of the surface of the sensitive diaphragm 210. It should be noted that in FIG. 50, the sensitive diaphragm support can not be seen directly, because the sensitive diaphragm support is shielded by the sensitive diaphragm support arm 231.

In other embodiments of the present invention, the MEMS microphone may also have a plurality of sensitive diaphragm supports, such as four sensitive diaphragm supports, five sensitive diaphragm supports or eight sensitive diaphragm supports. The sensitive diaphragm support may be located on the surface of the sensitive diaphragm 210, i.e., the center of a pattern formed by a plurality of sensitive diaphragm supports coincides with the center of the surface of the sensitive diaphragm 210.

Although preferred embodiments of the present invention have been disclosed above, which are not intended to limit the present invention, any possible variations and modifications can be made to the technical solution of the present invention by those skilled in the art according to the above-disclosed methods and technical contents without departing from the spirit and scope of the present invention. Therefore, any content which does not deviate from the technical solution of the present invention, and any modifications and equivalent variations made to the above embodiments according to the technical essence of the present invention will fall within the scope of protection of technical solution of the present invention.

1. A MEMS microphone, comprising:
a sensitive diaphragm and a fixed electrode corresponding to the sensitive diaphragm;
at least one sensitive diaphragm support located on the surface of the sensitive diaphragm corresponding to the fixed electrode; and
a sensitive diaphragm support arm coupled to the sensitive diaphragm support.

2. The MEMS microphone according to claim 1, wherein the sensitive diaphragm support is located in the center of the surface of the sensitive diaphragm corresponding to the fixed electrode, in the case where the number of the sensitive diaphragm support is 1.

3. The MEMS microphone according to claim 1, wherein the center of a pattern formed by a plurality of sensitive diaphragm supports coincides with the center of the surface of the sensitive diaphragm corresponding to the fixed electrode, in the case where the number of the sensitive diaphragm support is more than 1.

4. The MEMS microphone according to claim 1, wherein the fixed electrode, the sensitive diaphragm support and the sensitive diaphragm support arm are made from the same material.

5. The MEMS microphone according to claim 4, wherein the fixed electrode, the sensitive diaphragm support and the sensitive diaphragm support arm are made from low stress polycrystalline silicon.

6. The MEMS microphone according to claim 1, wherein the sensitive diaphragm support is made from a dielectric material.

7. The MEMS microphone according to claim 6, wherein the sensitive diaphragm support is made from silicon oxide.

8. The MEMS microphone according to claim 1, wherein the sensitive diaphragm support and the sensitive diaphragm are made from the same material.

9. The MEMS microphone according to claim 1, wherein the sensitive diaphragm support and the sensitive diaphragm are made from low stress polycrystalline silicon.

10. The MEMS microphone according to claim 1, further comprising: a travel stopper corresponding to the sensitive diaphragm and used to prevent the sensitive diaphragm from contacting the fixed electrode.

11. The MEMS microphone according to claim 10, wherein the travel stopper is made from a conductive material.

12. A method for forming the MEMS microphone as claimed in claim 1, comprising:
forming a sensitive diaphragm;
forming a fixed electrode;
forming at least one sensitive diaphragm support; and
forming a sensitive diaphragm support arm;
wherein the fixed electrode is corresponding to the sensitive diaphragm,
the sensitive diaphragm support is located on the surface of the sensitive diaphragm corresponding to the fixed electrode, and
the sensitive diaphragm support arm is coupled to the sensitive diaphragm support.

13. The method for forming the MEMS microphone according to claim 12, comprising:
forming a first electrode on a surface of a substrate;
forming a dielectric layer by which the first electrode is covered, and forming at least one sensitive diaphragm support within the dielectric layer;
forming a second electrode opposite to the first electrode, wherein the first electrode is the sensitive diaphragm and the second electrode is the fixed electrode; or the first electrode is the fixed electrode and the second electrode is the sensitive diaphragm; and
forming the sensitive diaphragm support arm, which is coupled to the sensitive diaphragm support on the surface of the sensitive diaphragm corresponding to the fixed electrode.

14. The method for forming the MEMS microphone according to claim 13, comprising:
forming the sensitive diaphragm on the surface of the substrate;
forming the dielectric layer by which the sensitive diaphragm is covered, and forming, within the dielectric layer, a through hole through which the surface of the sensitive diaphragm is exposed;
filling a low stress conductive material into the through hole, to form the sensitive diaphragm support in the position of the through hole and to form a low stress conductive layer on the surface of the dielectric layer; and
etching the low stress conductive layer to form, on the surface of the dielectric layer, the sensitive diaphragm support arm which is coupled to the sensitive diaphragm support, and the fixed electrode corresponding to the sensitive diaphragm.

15. The method for forming the MEMS microphone according to claim 13, comprising:
forming the sensitive diaphragm on the surface of the substrate;
forming the dielectric layer by which the sensitive diaphragm is covered;
forming, on the surface of the dielectric layer, the sensitive diaphragm support arm and the fixed electrode corresponding to the sensitive diaphragm, wherein the sensitive diaphragm support arm has a portion which has a position corresponding to the position of the sensitive diaphragm; and
etching the dielectric layer to form the sensitive diaphragm support coupling the sensitive diaphragm support arm to the sensitive diaphragm.

16. The method for forming the MEMS microphone according to claim 13, comprising:
forming, on the surface of the substrate, the sensitive diaphragm support arm and the fixed electrode;
forming the dielectric layer by which the sensitive diaphragm support arm and the fixed electrode are covered, and forming, within the dielectric layer, a through hole by which the surface of the sensitive diaphragm support arm is exposed;
filling a low stress conductive material into the through hole, to form the sensitive diaphragm support in the position of the through hole and to form a low stress conductive layer on the surface of the dielectric layer; and
etching the low stress conductive layer to form, on the surface of the dielectric layer, the sensitive diaphragm coupled to the sensitive diaphragm support and corresponding to the fixed electrode.

17. The method for forming the MEMS microphone according to claim 13, comprising:
forming, on the surface of the substrate, the sensitive diaphragm support arm and the fixed electrode;
forming the dielectric layer by which the sensitive diaphragm support arm and the fixed electrode are covered;
forming, on the surface of the dielectric layer, the sensitive diaphragm corresponding to the fixed electrode; and
etching the dielectric layer to form the sensitive diaphragm support coupling the sensitive diaphragm support arm to the sensitive diaphragm.

18. The method for forming the MEMS microphone according to claim 13, further comprising:
a step of forming a travel stopper, wherein the travel stopper is corresponding to the sensitive diaphragm and is used to prevent the sensitive diaphragm from contacting the fixed electrode.

19. The method for forming the MEMS microphone according to claim 18, wherein the travel stopper is formed in the same process step as the fixed electrode, or the travel stopper is formed in the same process step as the sensitive diaphragm support.
